(19) United States
(12) Patent Application Publication
(10) Pub. No.: US 2025/0330172 A1
(43) Pub. Date: Oct. 23, 2025

(54) SWITCH CONTROLLER WITH SEESAW DRIVER AND SWITCHING MODE DETECTION

(71) Applicant: TEXAS INSTRUMENTS INCORPORATED, Dallas, TX (US)

(72) Inventors: Raveesh MAGOD RAMAKRISHNA, Irving, TX (US); Nathan SCHEMM, Rowlett, TX (US)

(21) Appl. No.: 19/065,054

(22) Filed: Feb. 27, 2025

Related U.S. Application Data
(60) Provisional application No. 63/637,546, filed on Apr. 23, 2024.

(51) Int. Cl. H03K 17/16

(52) U.S. Cl. CPC H03K 17/166

(57) ABSTRACT

A circuit includes: a transistor; driver circuitry; and control circuitry. The control circuitry has a first terminal, a second terminal, and a set of third terminals. The first terminal of the control circuitry is coupled to a first terminal of the transistor. Each terminal of the set of third terminals of the control circuitry is coupled to a respective terminal of a set of first terminals of the driver circuitry. The control circuitry is configurable to: receive a voltage at the first terminal of the control circuitry; receive a first control signal at the second terminal of the control circuitry; identify a switching event for the transistor as a soft-switching event responsive to the voltage and the first control signal; and, in response to identifying the switching event for the transistor as a soft-switching event, adjust second control signals at the set of third terminals of the control circuitry.

The present application claims priority to U.S. Provisional Application No. 63/637,546, titled “Methodology to Detect Hard/Soft Switching in Power FETs”, Attorney Docket number T104706US01, filed on Apr. 23, 2024, which is hereby incorporated herein by reference in its entirety.

### BACKGROUND

Switching converters are used to provide a direct-current (DC) output voltage (VOUT) based on an input voltage (VIN). A typical switching converter includes: a power stage with switches and an inductor; and a controller for the switches of the power stage. Switch control affects switch slew rate, switch losses, and switch durability.

### SUMMARY

In an example, a circuit includes: a transistor; driver circuitry; and control circuitry. The transistor has a first terminal, a second terminal, and a control terminal. The driver circuitry has a set of first terminals, a second terminal, and a third terminal. The control circuitry having a first terminal, a second terminal, and a set of third terminals. The first terminal of the control circuitry are coupled to the first terminal of the transistor. The set of third terminals of the control circuitry are coupled to respective terminals of the set of first terminals of the driver circuitry. The control circuitry is configurable to: receive a voltage at the first terminal of the control circuitry; receive a first control signal at the second terminal of the control circuitry; identify a switching event for the transistor as a soft-switching event responsive to the voltage and the first control signal; and, in response to identifying the switching event for the transistor as a soft-switching event, adjust second control signals at the set of third terminals of the control circuitry.

In another example, an integrated circuit (IC) package includes: a transistor having a first terminal, a second terminal, and a control terminal; a first current source having a first terminal and a second terminal; a first switch between the second terminal of the first current source and the control terminal of the transistor; a second current source having a first terminal and a second terminal; and a second switch between the second terminal of the second current source and the control terminal of the transistor. IC package also includes control circuitry coupled to the first switch and the second switch. The control circuitry is configurable to: provide first control signals to the first switch and the second switch responsive to detecting a soft-switching event; and provide second control signals to the first switch and the second switch responsive to detecting a hard-switching event, the second control signals different than the first control signals.

In yet another example, an IC package includes: a gallium nitride (GaN) transistor; driver circuitry; and control circuitry. The GaN transistor has a first terminal, a second terminal, and a control terminal. The driver circuitry has a set of first terminals, a second terminal, and a third terminal. The third terminal of the driver circuitry is coupled to the control terminal of the GaN transistor. The driver circuitry includes: a first current source; a first switch between the first current source and the third terminal of the driver circuitry, the first switch having a control terminal; a second current source; a second switch between the second current source and the third terminal of the driver circuitry, the second switch having a control terminal; and a second transistor between the second terminal of the driver circuitry and the third terminal of the driver circuitry. The control circuitry is coupled to the control terminal of the first switch and the control terminal of the second switch. The control circuitry is configurable to: provide first control signals to the control terminal of the first switch and the control terminal of the second switch responsive to detecting a soft-switching event; and provide second control signals to the control terminal first switch and the control terminal of the second switch responsive to detecting a hard-switching event, the second control signals different than the first control signals.

### BRIEF DESCRIPTION OF THE DRAWINGS

FIG. 1 is a diagram showing an example system.

FIG. 2 is a diagram showing another example system.

FIG. 3 is a diagram showing example integrated circuit dies.

FIG. 4 is a timing diagram showing different driver control modes and related waveforms.

FIG. 5 is a timing diagram showing example system waveforms for different modes.

FIG. 6 is a schematic diagram showing an example first current source of a seesaw driver.

FIG. 7 is a schematic diagram showing an example switch circuit of a seesaw driver.

FIG. 8 is a schematic diagram showing an example second current source of a seesaw driver.

FIG. 9 is a schematic diagram showing example voltage transition detection circuitry of a seesaw driver.

FIG. 10 is a schematic diagram showing other example voltage transition detection circuitry of a seesaw driver.

FIG. 11 is a timing diagram showing example system signals for a hard-switching event.

FIG. 12 is a timing diagram showing example system signals for a soft-switching event.

FIG. 13 is a flowchart showing an example seesaw driver control method.

### DETAILED DESCRIPTION

The same reference numbers or other reference designators are used in the drawings to designate the same or similar features. Such features may be the same or similar either by function and/or structure.

Described herein is seesaw driver and control circuitry that performs switching mode detection as part of controlling a target switch having a first terminal, a second terminal, and a control terminal. Example switching mode detection includes soft-switching event detection and/or hard-switching event detection. As used herein, a “soft-switching event” refers to a switching event for the target switch, where the switch is turned on when the voltage across the first and second terminals of the target switch is zero or very close to zero (e.g., within a target threshold to zero). As used herein, a “partial soft-switching event” refers to a switching event for the target switch, where the target switch is turned on when the voltage across the first and second terminals of the target switch is falling from a steady-state value and is below a threshold. As used herein, a “hard-switching event” refers to a switching event for the target switch, where the target switch is turned on when the voltage across the first and second terminals of the target switch is not falling and is the steady-state value. In response to soft-switching event detection, the seesaw driver and control circuitry initiates resistive pull-up mode (or just pull-up mode herein) operations and seesaw mode operations are avoided. In response to hard-switching event detection, the seesaw driver and control circuitry initiates seesaw mode operations.

In some examples, the seesaw mode operations include modulating a drive current (I_{DRV}) during different control phases. Modulating I_{DRV} controls a first voltage (e.g., a gate-to-source voltage (V_{GS})) of the target switch. In some example, the seesaw driver and control circuitry modulates I_{DRV} up and down during the different control phases until the first voltage reaches a target level. In one example, I_{DRV} is increased during a first control phase in which the first voltage (e.g., V_{GS}) is initially below a threshold voltage (V_{TH}) for the target switch. I_{DRV} is maintained at the increased level as the V_{GS} of the target switch increases above V_{TH} and VDS of the target switch remains above a pre-determined threshold value. During a second control phase in which a second voltage (e.g., a drain-to-source voltage (V_{DS})) of the target switch decreases, I_{DRV} is decreased. After the second control phase, a third control phase (e.g., a pull-up phase) is initiated in which I_{DRV} is increased relative to I_{DRV} during the second control phase, then I_{DRV} is gradually decreased. With the seesaw driver and control circuitry, control of V_{GS} during a soft-switching event is improved compared to previous control techniques, reducing or eliminating V_{GS} overshoot. As used herein, “seesaw I_{DRV} modulation” refers to I_{DRV} being adjusted up and down at least twice during the different control phases.

In some examples, the target switch is a GaN transistor or enhanced (or enhancement-mode) GaN (eGaN) transistor. As used herein, an eGaN transistor uses a positive gate voltage to turn on with the fast switching speeds of GaN. The GaN transistor may be part of a switching converter power stage (e.g., a buck converter, a boost converter, or a buck-boost converter). Use of the seesaw driver and control circuitry with switching mode detection for a GaN transistor ensures low overlap loss and eliminates the possibility of overshoot in the V_{GS} of the GaN transistor, improving gate reliability. In some examples, a seesaw driver and control circuitry includes: a robust sensing line with always-on pull-up resistance on the sense line (e.g., a high-voltage cap divider); always on dVdt detection for soft-switching event detection; a blanking circuit to block glitches due to V_{DS} transition of the target switch; control logic to differentiate between different switching modes of the target switch; seamless turn-on of the target switch irrespective of the dVdt setting; lower gate stress on target switch improving its time-dependent dielectric breakdown (TDDB) performance and reduction of gate leakage; and target switch durability.

In some examples, an integrated circuit package includes a GaN transistor and seesaw driver and control circuitry. The GaN transistor may be on a first die of the IC package while the seesaw driver and control circuitry are on a second die of the IC package. The control circuitry detects if the GaN transistor is subject to a hard-switching event or a soft-switching event. In response to detecting a hard-switching event (e.g., when the GaN transistor is used as a high-side switch in a switching converter), the seesaw driver and control circuitry applies seesaw I_{DRV} modulation to adjust V_{GS} for the GaN transistor. In response to detecting a soft-switching event (e.g., when the GaN transistor is used as a low-side switch in a switching converter), the seesaw driver and control circuitry applies a resistive pull-up mode to drive V_{GS} for the GaN transistor to a target steady-state voltage VDRV.

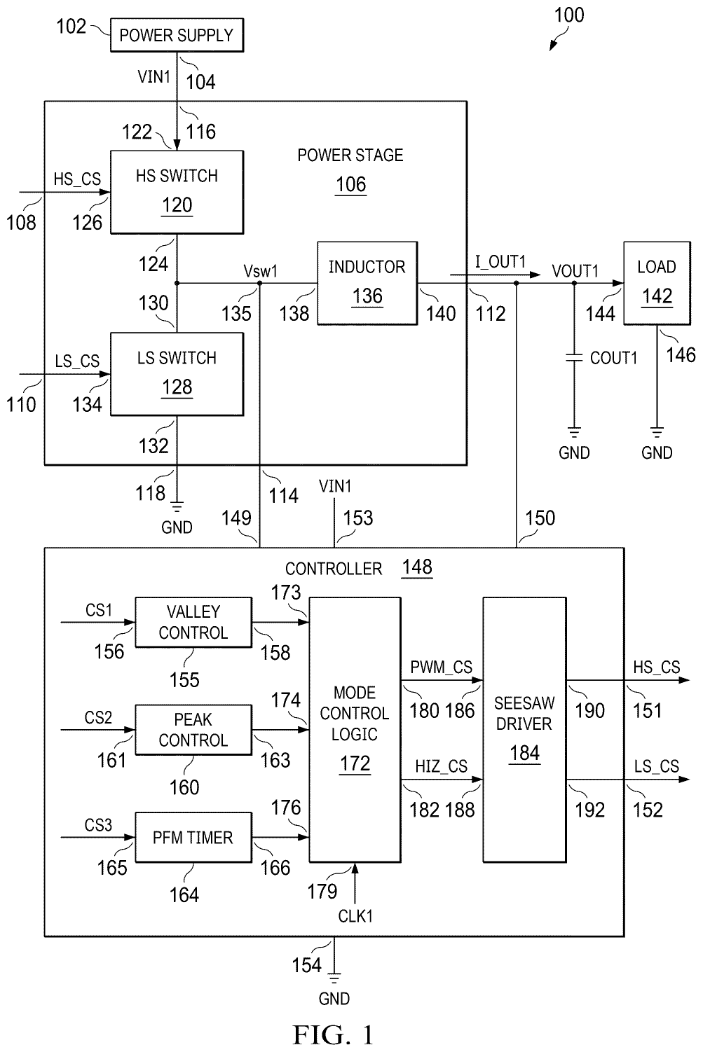

FIG. 1 is a diagram showing an example system 100. The system 100 includes a power supply 102, a power stage 106, an output capacitor COUT1, a load 142, and a controller 148. The power supply 102 has a terminal 104. The power stage 106 has a first terminal 108, a second terminal 110, a third terminal 112, a fourth terminal 114, a fifth terminal 116, and a sixth terminal 118. The output capacitor COUT1 has a first terminal and a second terminal. The load 142 has a first terminal 144 and a second terminal 146. The controller 148 has a first terminal 149, a second terminal 150, a third terminal 151, a fourth terminal 152, a fifth terminal 153, and a sixth terminal 154.

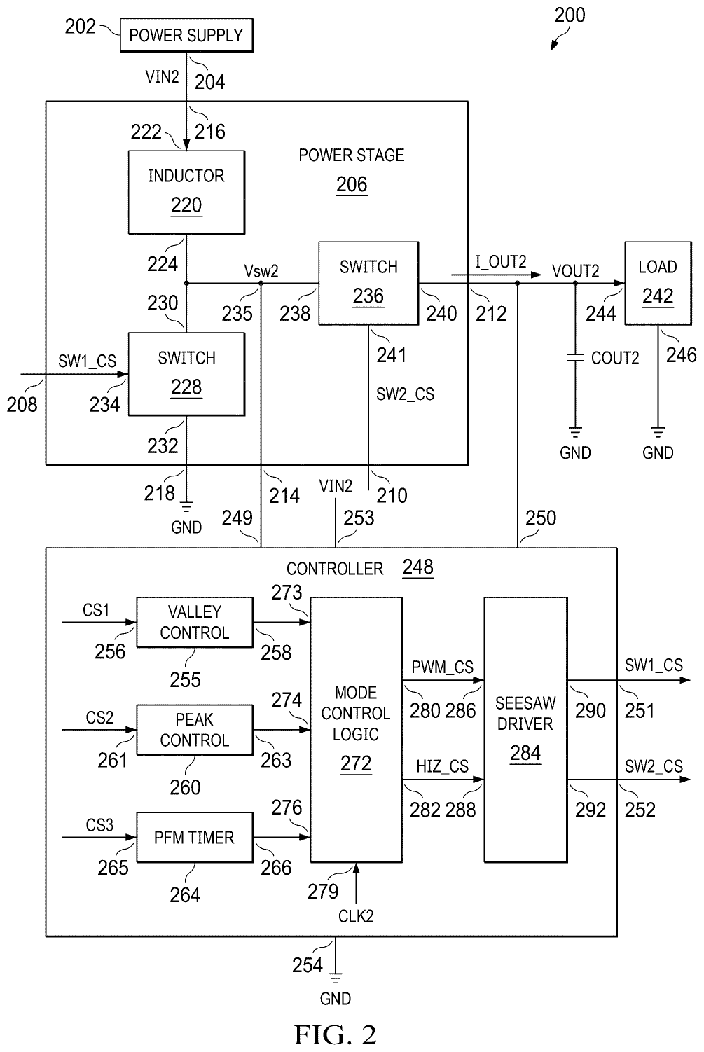

As shown, the power stage 106 includes a high-side (HS) switch 120, a low-side (LS) switch 128, and an inductor 136 in the arrangement shown. In some examples, the HS switch 120, LS switch 128, and related control circuitry are components of an integrated circuit (IC), while the inductor 136 is an external component relative to the IC. The arrangement of components for the power stage 106 of FIG. 1 is referred to as a buck converter topology, where the output voltage VOUT is lower than the input voltage VIN. In other examples, the topology of the power stage 106 may vary (e.g., a boost converter topology as in FIG. 2, or a boost-buck converter topology may be used). In the example of FIG. 1, the HS switch 120 has a first terminal 122, a second terminal 124, and a control terminal 126. The LS switch 128 has a first terminal 130, a second terminal 132, and a control terminal 134. In some examples, the HS switch 120 may be a p-channel field-effect transistor (“PFET”) or an n-channel field-effect transistor (“NFET”), and the LS switch 128 may be an NFET. The inductor 136 has a first terminal 138 and a second terminal 140.

The controller 148 includes valley control circuitry 155, peak control circuitry 160, pulse-frequency modulation (PFM) timer circuitry 164, mode control logic 172, and seesaw driver and control circuitry 184. The valley control circuitry 155 has first terminal(s) 156 and a second terminal 158. The peak control circuitry 160 has first terminal(s) 161 and a second terminal 163. The PFM timer circuitry 164 has first terminal(s) 165 and a second terminal 166. The mode control logic 172 has a first terminal 173, a second terminal 174, a third terminal 176, a fourth terminal 179, a fifth terminal 180, and a sixth terminal 182. The seesaw driver and control circuitry 184 has a first terminal 186, a second terminal 188, a third terminal 190, and a fourth terminal 192.

The first terminal 108 of the power stage 106 is coupled to the third terminal 151 of the controller 148. The second terminal 110 of the power stage 106 is coupled to the fourth terminal 152 of the controller 148. The third terminal 112 of the power stage 106 is coupled to the first terminal of the output capacitor COUT1, the first terminal 144 of the load 142, and the second terminal 150 of the controller 148. The second terminal of the output capacitor COUT1 is coupled to ground or a ground terminal. The second terminal 146 of the load 142 is coupled to ground or a ground terminal. The fourth terminal 114 of the power stage 106 is coupled to the first terminal 149 of the controller 148. The fifth terminal 116 of the power stage 106 is coupled to the terminal 104 of the power supply 102. The terminal 104 of the power supply 102 is also coupled to the fifth terminal 153 of the controller 148. The sixth terminal 118 of the power stage 106 is coupled to ground or a ground terminal. The sixth terminal 154 of the controller 148 is also coupled to ground or a ground terminal.

As shown, the first terminal 122 of the HS switch 120 is coupled to the fifth terminal 116 of the power stage 106. The second terminal 124 of the HS switch 120 is coupled to the first terminal 130 of the LS switch 128 and to the first terminal 138 of the inductor 136. The second terminal 140 of the inductor 136 is coupled to the third terminal 112 of the power stage 106. The control terminal 126 of the HS switch 120 is coupled to the first terminal 108 of the power stage 106. The second terminal 132 of the LS switch 128 is coupled to the sixth terminal 118 of the power stage 106. The control terminal 134 of the LS switch 128 is coupled to the second terminal 110 of the power stage 106. As shown, the fourth terminal 114 of the power stage is coupled to a switch node 135 between the HS switch 120 and the LS switch 128.

As shown, the first terminal(s) 156 of the valley control circuitry 155 receive control signal(s) CS1. In some examples, CS1 includes a valley threshold and an inductor current sense signal. In some examples, the valley threshold and/or the inductor current sense signal are ramped. The first terminal(s) 161 of the peak control circuitry 160 receive control signal(s) CS2. In some examples, CS2 includes a peak threshold and an inductor current sense signal. The first terminal(s) 165 of the PFM timer circuitry 164 receive control signal(s) CS3. In some examples, CS3 includes a control voltage (e.g., V_CTRL herein). In some examples, V_CTRL is the error result between VOUT and a reference voltage (VREF).

The first terminal 173 of the mode control logic 172 is coupled to the second terminal 158 of the valley control circuitry 155. The second terminal 174 of the mode control logic 172 is coupled to the second terminal 163 of the peak control circuitry 160. The third terminal 176 of the mode control logic 172 is coupled to the second terminal 166 of the PFM timer circuitry 164. The fourth terminal 179 of the mode control logic 172 receives a clock signal (CLK1). The fifth terminal 180 of the mode control logic 172 is coupled to the first terminal 186 of the seesaw driver and control circuitry 184. The sixth terminal 182 of the mode control logic 172 is coupled to the second terminal 188 of the seesaw driver and control circuitry 184. The third terminal 190 of the seesaw driver and control circuitry 184 is coupled to the third terminal 151 of the controller 148. The fourth terminal 192 of the seesaw driver and control circuitry 184 is coupled to the fourth terminal 152 of the controller 148.

In operation, the controller 148 is configurable to: receive VIN1 at its fifth terminal 153; receive V_{SW1} at its first terminal 149; receive VOUT1 at its second terminal 150; provide a high-side control signal (HS_CS) at its third terminal 151 responsive to VIN1, V_{SW1}, VOUT1, and the operations of the valley control circuitry 155, the peak control circuitry 160, the PFM timer circuitry 164, the mode control logic 172, and the seesaw driver and control circuitry 184; and provide a low-side control signal (LS_CS) at its fourth terminal 152 responsive to VIN1, V_{SW1}, VOUT11, and the operations of the valley control circuitry 155, the peak control circuitry 160, the PFM timer circuitry 164, the mode control logic 172, and the seesaw driver and control circuitry 184.

In some examples, modes supported by the controller 148 include a pulse-width modulation (PWM) mode and a PFM mode. In some examples, the valley control circuitry 155, the peak control circuitry 160, the PFM timer circuitry 164 may provide respective standalone control options for the controller 148 (i.e., only one of the valley control circuitry 155, the peak control circuitry 160, and the PFM timer circuitry 164 is active). In other examples, the valley control circuitry 155, the peak control circuitry 160, the PFM timer circuitry 164 may provide different combinations of control options. In one example, the valley control circuitry 155 and the peak control circuitry 160 are active together. In another example, the valley control circuitry 155 and the PFM timer circuitry 164 are active together. In another example, the peak control circuitry 160 and the PFM timer circuitry 164 are active together. In another example, the valley control circuitry 155, the peak control circuitry 160, and the PFM timer circuitry 164 are active together.

The mode control logic 172 is configurable to: receive valley control results from the valley control circuitry 155 at the first terminal 173; receive peak control results from the peak control circuitry 160 at the second terminal 174; receive PFM timer results from the PFM timer circuitry 164 at the third terminal 176; receive a clock signal (CLK1) at the fourth terminal; provide a PWM control signal (PWM_CS) at the fifth terminal 180 responsive to the valley control results, the peak control results, and/or the PFM timer results; and provide a high-impedance control signal (HIZ_CS) at the sixth terminal 182 responsive to the valley control results, the peak control results, and/or the PFM timer results.

In the example of FIG. 1, the seesaw driver and control circuitry 184 is configurable to: receive PWM_CS at the first terminal 186; receive HIZ_CS at the second terminal 188; provide HS_CS at the third terminal 190 responsive to PWM_CS and/or HIZ_CS; and provide LS_CS at the fourth terminal 192 responsive to PWM_CS and/or HIZ_CS. In some examples, the seesaw driver and control circuitry 184 performs soft-switching event detection and/or hard-switching event detection. In response to a soft-switching event, the seesaw driver and control circuitry 184 initiates resistive pull-up mode operations (seesaw mode operations are avoided). In response to a hard-switching event, the seesaw driver and control circuitry initiates seesaw mode operations. In some examples, the seesaw mode operations of the seesaw driver and control circuitry 184 include modulating I_{DRV} during different control phases. Modulating I_{DRV} controls V_{GS} of a target switch. In some example, the seesaw driver and control circuitry 184 modulates I_{DRV} up and down during the different control phases until V_{GS} of the target switch reaches a target level. In one example, I_{DRV} is increased during a first control phase in which V_{GS} of the target switch is below V_{TH} for the target switch. I_{DRV} is maintained at the increased level even as the V_{GS} of the target switch goes above V_{TH} for the target switch and V_{DS} of the target switch remains at above a pre-determined threshold value. During a second control phase in which V_{DS} of the target switch decreases below a threshold voltage from its steady-state voltage, I_{DRV} is decreased. After the second control phase, a third control phase (e.g., a pull-up phase) is initiated in which I_{DRV} is increased relative to I_{DRV} during the second control phase, and gradually decreases as the V_{GS} reaches the steady-state voltage. With the seesaw driver and control circuitry 184, control of V_{GS} responsive to a soft-switching event is improved compared to previous control techniques, reducing or eliminating V_{GS} overshoot.

In operation, the power stage 106 is configurable to: receive VIN1 at its fifth terminal 116; receive HS_CS at its first terminal 108; receive LS_CS at its second terminal 110; provide VOUT1 at its third terminal 112 responsive to VIN1, HS_CS, and LS_CS; and provide V_{SW1} at its fourth terminal 114 responsive to VIN1, HS_CS, and LS_CS. More specifically, the HS switch 120 couples VIN1 to the switch node 135 responsive to HS_CS, which increases the current in the inductor 136. The LS switch 128 couples the sixth terminal 118 to the switch node 135 responsive to LS_CS, which decreases the current in the inductor 136. The average current in the inductor 136 is considered the load current (I_out1) provided to the load 142. In some examples, VIN1 may be 400V and VOUT1 may be 48V. In some examples, I_out1 may be 1 A during PFM mode. During PWM mode, I_out1 may be 20 A.

FIG. 2 is a diagram showing another example system 200. Compared to the system 100, the system 200 includes a boost converter topology instead of a buck converter topology. The system 200 includes a power supply 202, a power stage 206, an output capacitor COUT2, a load 242, and a controller 248. The power supply 202 has a terminal 204. The power stage 206 has a first terminal 208, a second terminal 210, a third terminal 212, a fourth terminal 214, a fifth terminal 216, and a sixth terminal 218. The output capacitor COUT2 has a first terminal and a second terminal. The load 242 has a first terminal 244 and a second terminal 246. The controller 248 has a first terminal 249, a second terminal 250, a third terminal 251, a fourth terminal 252, a fifth terminal 253, and a sixth terminal 254.

As shown, the power stage 206 includes an inductor 220, a first switch 228, and a second switch 236 in the arrangement shown. In some examples, the first switch 228, the second switch 236, and related control circuitry are components of an IC, while the inductor 220 is an external component relative to the IC. The arrangement of components for the power stage 206 of FIG. 2 is referred to as a boost converter topology, where the output voltage VOUT2 is the same or is higher than the input voltage VIN2. In other examples, a power stage may have a buck-boost converter topology. In the example of FIG. 2, the first switch 228 has a first terminal 230, a second terminal 232, and a control terminal 234. The second switch 236 has a first terminal 238, a second terminal 240, and a control terminal 241. In some examples, the first switch 228 may be NFET, and the second switch 236 may be a PFET or an NFET. The inductor 220 has a first terminal 222 and a second terminal 224.

The controller 248 includes valley control circuitry 255, peak control circuitry 260, PFM timer circuitry 264, mode control logic 272, and seesaw driver and control circuitry 284. The valley control circuitry 255 has first terminal(s) 256 and a second terminal 258. The peak control circuitry 260 has first terminal(s) 261 and a second terminal 263. The PFM timer circuitry 264 has first terminal(s) 265 and a second terminal 266. The mode control logic 272 has a first terminal 273, a second terminal 274, a third terminal 276, a fourth terminal 279, a fifth terminal 280, and a sixth terminal 282. The seesaw driver and control circuitry 284 has a first terminal 286, a second terminal 288, a third terminal 290, and a fourth terminal 292.

The first terminal 208 of the power stage 206 is coupled to the third terminal 251 of the controller 248. The second terminal 210 of the power stage 206 is coupled to the fourth terminal 252 of the controller 248. The third terminal 212 of the power stage 106 is coupled to the first terminal of the output capacitor COUT2, the first terminal 244 of the load 142, and the second terminal 250 of the controller 248. The second terminal of the output capacitor COUT2 is coupled to ground or a ground terminal. The second terminal 246 of the load 242 is coupled to ground or a ground terminal. The fourth terminal 214 of the power stage 206 is coupled to the first terminal 249 of the controller 248. The fifth terminal 216 of the power stage 206 is coupled to the terminal 204 of the power supply 202. The terminal 204 of the power supply 202 is also coupled to the fifth terminal 253 of the controller 248. The sixth terminal 218 of the power stage 206 is coupled to ground or a ground terminal. The sixth terminal 254 of the controller 248 is also coupled to ground or a ground terminal.

As shown, the first terminal 222 of the inductor 220 is coupled to the fifth terminal 216 of the power stage 106. The second terminal 224 of the inductor 220 is coupled to the first terminal 230 of the first switch 228 and to the first terminal 238 of the second switch 236. The second terminal 232 of the first switch 228 is coupled to the sixth terminal 218 of the power stage 206. The control terminal 234 of the first switch 228 is coupled to the first terminal 208 of the power stage 206. The second terminal 240 of the second switch 236 is coupled to the third terminal 212 of the power stage 206. The control terminal 241 of the second switch 236 is coupled to the second terminal 210 of the power stage 106. As shown, the fourth terminal 214 of the power stage is coupled to a switch node 235 between the first switch 228 and the second switch 236.

As shown, the first terminal(s) 256 of the valley control circuitry 255 receive control signal(s) CS1. In some examples, CS1 includes a valley threshold and an inductor current sense signal. In some examples, the valley threshold and/or the inductor current sense signal are ramped. The first terminal(s) 261 of the peak control circuitry 260 receive control signal(s) CS2. In some examples, CS2 includes a peak threshold and an inductor current sense signal. The first terminal(s) 265 of the PFM timer circuitry 264 receive control signal(s) CS3. In some examples, CS3 includes a control voltage (e.g., V_CTRL herein). In some examples, V_CTRL is the error result between VOUT and a reference voltage (VREF).

The first terminal 273 of the mode control logic 272 is coupled to the second terminal 258 of the valley control circuitry 255. The second terminal 274 of the mode control logic 272 is coupled to the second terminal 263 of the peak control circuitry 260. The third terminal 276 of the mode control logic 272 is coupled to the second terminal 266 of the PFM timer circuitry 264. The fourth terminal 279 of the mode control logic 272 receives a clock signal (CLK2). The fifth terminal 280 of the mode control logic 272 is coupled to the first terminal 286 of the seesaw driver and control circuitry 284. The sixth terminal 282 of the mode control logic 272 is coupled to the second terminal 288 of the seesaw driver and control circuitry 284. The third terminal 290 of the seesaw driver and control circuitry 284 is coupled to the third terminal 251 of the controller 248. The fourth terminal 292 of the seesaw driver and control circuitry 284 is coupled to the fourth terminal 252 of the controller 248.

In operation, the controller 248 is configurable to: receive VIN2 at its fifth terminal 253; receive V_{SW2} at its first terminal 249; receive VOUT2 at its second terminal 250; provide SW1_CS at its third terminal 251 responsive to VIN2, V_{SW2}, VOUT2, and the operations of the valley control circuitry 255, the peak control circuitry 260, the PFM timer circuitry 264, the mode control logic 272, and the seesaw driver and control circuitry 284; and provide SW2_CS at its fourth terminal 252 responsive to VIN2, V_{SW2}, VOUT2, and the operations of the valley control circuitry 255, the peak control circuitry 260, the PFM timer circuitry 264, the mode control logic 272, and the seesaw driver and control circuitry 284. In some examples, modes supported by the controller 248 include a PWM mode and a PFM mode.

In some examples, modes supported by the controller 248 include a pulse-width modulation (PWM) mode and a PFM mode. In some examples, the valley control circuitry 155, the peak control circuitry 160, the PFM timer circuitry 164 may provide respective standalone control options for the controller 248 (i.e., only one of the valley control circuitry 255, the peak control circuitry 260, and the PFM timer circuitry 264 is active). In other examples, the valley control circuitry 255, the peak control circuitry 260, the PFM timer circuitry 264 may provide different combinations of control options. In one example, the valley control circuitry 255 and the peak control circuitry 260 are active together. In another example, the valley control circuitry 255 and the PFM timer circuitry 264 are active together. In another example, the peak control circuitry 260 and the PFM timer circuitry 264 are active together. In another example, the valley control circuitry 255, the peak control circuitry 260, and the PFM timer circuitry 264 are active together.

The mode control logic 272 is configurable to: receive valley control results from the valley control circuitry 255 at the first terminal 273; receive peak control results from the peak control circuitry 260 at the second terminal 274; receive PFM timer results from the PFM timer circuitry 264 at the third terminal 276; receive a clock signal (CLK2) at the fourth terminal; provide a PWM control signal (PWM_CS) at the fifth terminal 280 responsive to the valley control results, the peak control results, and/or the PFM timer results; and provide a high-impedance control signal (HIZ_CS) at the sixth terminal 282 responsive to the valley control results, the peak control results, and/or the PFM timer results.

In the example of FIG. 2, the seesaw driver and control circuitry 284 is configurable to: receive PWM_CS at the first terminal 286; receive HIZ_CS at the second terminal 288; provide a first control signal (SW1_CS) at the third terminal 190 responsive to PWM_CS and/or HIZ_CS; and provide a second control signal (SW2_CS) at the fourth terminal 192 responsive to PWM_CS and/or HIZ_CS. In some examples, the seesaw driver and control circuitry 284 performs soft-switching event detection and/or hard-switching event detection. In response to a soft-switching event, the seesaw driver and control circuitry 284 initiates resistive pull-up mode operations (seesaw mode operations (described below) are avoided). In response to a hard-switching event, the seesaw driver and control circuitry initiates seesaw mode operations. In some examples, the seesaw mode operations of the seesaw driver and control circuitry 284 include modulating I_{DRV} during different control phases. Modulating I_{DRV} controls V_{GS} of a target switch. In some example, the seesaw driver and control circuitry 284 modulates I_{DRV} up and down during the different control phases until V_{GS} of the target switch reaches a target level. In one example, I_{DRV} is increased during a first control phase in which V_{GS} of the target switch is below V_{TH} for the target switch. The I_{DRV} is kept increased even as the V_{GS} of the target switch goes above V_{TH} for the target switch and V_{DS} of the target switch remains at above a pre-determined threshold value. During a second control phase in which V_{DS} of the target switch decreases below a threshold voltage from its steady-state voltage, I_{DRV} is decreased. After the second control phase, a third control phase (e.g., a pull-up phase) is initiated in which I_{DRV} is increased relative to I_{DRV} during the second control phase, and gradually decreases as the V_{GS} reaches the steady-state voltage. With the seesaw driver and control circuitry 184, control of V_{GS} responsive to a soft-switching event is improved compared to previous control techniques, reducing or eliminating V_{GS} overshoot.

In operation, the power stage 206 is configurable to: receive VIN2 at its fifth terminal 216; receive SW1_CS at its first terminal 208; receive SW2_CS at its second terminal 210; provide VOUT2 at its third terminal 212 responsive to VIN2, SW1_CS, and SW2_CS; and provide V_{SW2} at its fourth terminal 214 responsive to VIN2, SW1_CS, and SW2_CS. More specifically, when the first switch 228 is on and the second switch 236 is off, current in the inductor 220 increases. When the first switch 228 is off and the second switch 236 is on, current in the inductor 220 decreases. The average current in the inductor 136 is considered the load current (I_out2) provided to the load 242.

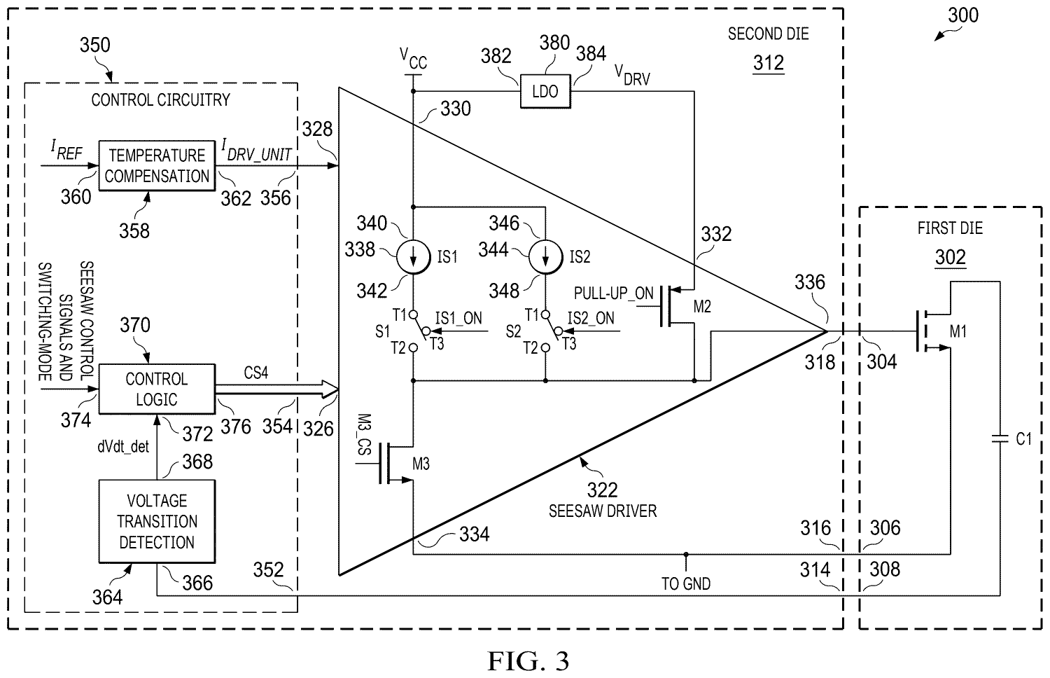

FIG. 3 is a diagram 300 showing example IC dies including a first die 302 and a second die 312. The first die 302 has a first terminal 304, a second terminal 306, and a third terminal 308. The first die 302 includes a transistor M1 and a capacitor C1. The transistor M1 has a first terminal, a second terminal, and a control terminal. In the example of FIG. 3, the transistor M1 is an N-channel metal oxide semiconductor (“NMOS”) transistor. In some examples, the transistor M1 is a GaN transistor. The capacitor C1 has a first terminal and a second terminal.

The second die 312 has a first terminal 314, a second terminal 316, and a third terminal 318. The second die 312 includes seesaw driver circuitry 322, control circuitry 350, and a low dropout regulator (LDO) 380. In some examples, the seesaw driver circuitry 322 and the control circuitry 350 are part of the seesaw driver and control circuitry 184 in FIG. 1, or part of the seesaw driver and control circuitry 284 in FIG. 2.

In the example of FIG. 3, the seesaw driver circuitry 322 has a set of first terminals 326, a second terminal 328, a third terminal 330, a fourth terminal 332, a fifth terminal 334, and a sixth terminal. The set of first terminals 326 of the seesaw driver circuitry 322 are examples of the first terminal 186 and the second terminal 188 in FIG. 1, or of the first terminal 286 and the second terminal 288 in FIG. 2. The sixth terminal 336 of the seesaw driver circuitry 322 is an example of the third terminal 190 in FIG. 1, the fourth terminal 192 in FIG. 1, the third terminal 290 in FIG. 2, or the fourth terminal 292 in FIG. 2.

The seesaw driver circuitry 322 includes a first current source 338, a first switch S1, a second current source 344, a second switch S2, and transistors M2 and M3. The first current source 338 has a first terminal 340 and a second terminal 342. The first switch S1 has a first terminal T1, a second terminal T2, and a control terminal T3. The second current source 344 has a first terminal 346 and a second terminal 348. The second switch S2 has a first terminal T1, a second terminal T3, and a control terminal T3. The transistor M2 has a first terminal, a second terminal, and a control terminal. The transistor M3 has a first terminal, a second terminal, and a control terminal. In the example of FIG. 3, the transistor M2 is a p-channel metal oxide semiconductor (“PMOS”), and the M3 transistor is an NMOS transistor.

The control circuitry 350 has a first terminal 352, a set of second terminals 354, and a third terminal 356. The control circuitry 350 includes temperature compensation circuitry 358, voltage transition detection circuitry 364, and control logic 370. The temperature compensation circuitry 358 has a first terminal 360 and a second terminal 362. The voltage transition detection circuitry 364 has a first terminal 366 and a second terminal 368. The control logic 370 has a first terminal 372, a second terminal 374, and a set of third terminals 376.

The first terminal 304 of the first die 302 is coupled to the control terminal of the transistor M1. The first terminal of the transistor M1 is coupled to the first terminal of the capacitor C1. The second terminal of the transistor M1 is coupled to the second terminal 306 of the first die 302. The second terminal of the capacitor C1 is coupled to the third terminal 308 of the first die 302.

The first terminal 314 of the second die 312 is coupled to the third terminal 308 of the first die 302 and the first terminal 352 of the control circuitry 350. The second terminal 316 of the second die 312 is coupled to the second terminal 306 of the first die 302 and the fifth terminal 334 of the seesaw driver circuitry 322. The third terminal 318 of the second die 312 is coupled to the first terminal 304 of the first die 302 and the sixth terminal 336 of the seesaw driver circuitry 322. The set of first terminals 326 of the seesaw driver circuitry 322 is coupled to the set of second terminals 354 of the control circuitry 350. The second terminal 328 of the seesaw driver circuitry 322 is coupled to the third terminal 356 of the control circuitry 350. The third terminal 330 of the seesaw driver circuitry 322 is coupled to the first terminal 382 of the LDO 380. The fourth terminal 332 of the seesaw driver circuitry 322 is coupled to the second terminal 384 of the LDO 380.

The first terminal 340 of the first current source 338 and the first terminal 346 of the second current source 344 are coupled to the third terminal 330 of the seesaw driver circuitry 322. The second terminal 342 of the first current source 338 is coupled to the first terminal T1 of the switch S1. The second terminal T2 of the switch S1 is coupled to the first terminal of the transistor M3 and the sixth terminal 336 of the seesaw driver circuitry 322. The control terminal T3 of the switch S1 is coupled to a respective terminal of the set of first terminals 326 of the seesaw driver circuitry 322. The second terminal of the transistor M3 is coupled to the fifth terminal 334 of the seesaw driver circuitry 322. The control terminal of the transistor M3 is coupled to a respective terminal of the set of the first terminals 326 of the seesaw driver circuitry 322. The second terminal 348 of the second current source 344 is coupled to the first terminal T1 of the switch S2. The second terminal T2 of the switch S2 is coupled to the first terminal of the transistor M3 and the sixth terminal 336 of the seesaw driver circuitry 322. The control terminal T3 of the switch S2 is coupled to a respective terminal of the set of first terminals 326 of the seesaw driver circuitry 322. The first terminal of the transistor M2 is coupled to the fourth terminal 332 of the seesaw driver circuitry 322. The second terminal of the transistor M2 is coupled to the first terminal of the transistor M3 and the sixth terminal 336 of the seesaw driver circuitry 322. The control terminal of the transistor M2 is coupled to a respective terminal of the set of the first terminals 326 of the seesaw driver circuitry 322. In the example of FIG. 3, the fifth terminal 334 of the seesaw driver circuitry 322 is coupled to ground or a ground terminal.

The first terminal 352 of the control circuitry 350 is coupled to the first terminal 366 of the voltage transition detection circuitry 364. The second terminal 368 of the voltage transition detection circuitry 364 is coupled to the first terminal 372 of the control logic 370. The set of third terminals 376 of the control logic 370 is coupled to the set of second terminals 354 of the control circuitry 350. The second terminal 362 of the temperature compensation circuitry 358 is coupled to the third terminal 356 of the control circuitry 350.

In the example of FIG. 3, the control circuitry 350 is configurable to: receive Vos of the transistor M1 via the capacitor C1; detect a transition in V_{DS} using the voltage transition detection circuitry 364; provide a temperature compensation signal (I_{DRV_UNIT}); and provide the control signals CS4 using the control logic 370 responsive to seesaw control signals, a switching mode, and V_{DS} transition results. In the example of FIG. 3, the control circuitry is configurable to: receive V_{DS} of the transistor M1 at the first terminal 352 of the control circuitry 350; provide respective control signals of the control signals CS4 to respective terminals of the set of second terminals 354 of the control circuitry 350; and provide I_{DRV_UNIT} at the third terminal 356 of the control circuitry 350.

In some examples, the switch S2 and the second current source 344 are in parallel with the transistor M3, where the transistor M3 operates as a pull-down transistor and the second current source 344 operates as a current sink. In such examples, the first terminal t1 of the switch S2 is coupled to the second terminal t2 of the first switch S1. The second terminal of the switch S2 is coupled to the first terminal 346 of the second current source 344. The second terminal 348 of the second current source 344 is coupled to the fifth terminal 334 of the seesaw driver circuitry 322. In such examples, the first terminal of the transistor M3 is coupled to the first terminal t1 of second switch S2, and the second terminal of the transistor M3 is coupled to the fifth terminal 334 of the seesaw driver circuitry 322.

The seesaw driver circuitry 322 is configurable to: receive the control signals CS4 at the set of first terminals 326; receive I_{DRV_UNIT} at the second terminal 328; receive a power supply (V_{CC}) at the third terminal 330; receive a drive voltage (V_{DRV}) at the fourth terminal 332; and provide I_{DRV} at the sixth terminal 336 responsive to the control signals CS4, I_{DRV_UNIT}, V_{CC}, and the operations of the first current source 338, the second current source 344, the first switch S1, the second switch S2, the transistor M2, and the transistor M3. More specifically, the first current source 338 selectively contributes a first current IS1 to I_{DRV} via the first switch S1. The second current source 344 selectively contributes a second current IS2 to I_{DRV} via the second switch S2. In different examples, the first current IS1 and the second current IS2 may be applied together or separately. In some examples, the second current IS2 is a current sink. As shown, the first switch S1 is controlled by a control signal IS2_ON, the second switch S2 is controlled by a control signal IS2_ON, the transistor M2 is controlled by a PULL-UP_ON control signal, and the transistor M3 is controlled by a control signal M3_CS. In some examples, the control circuitry 350 performs soft-switching event detection. In response to a soft-switching event, the control circuitry 350 asserts CC_MODE_ON. In some examples, the control signals CS4 from the control circuitry 350 include the control signals IS1_ON, IS2_ON, PULL-UP_ON, and M3_CS. In some examples, I_{DRV_UNIT} is the fundamental temperature compensated unit current which decides the final falling slew rate of the V_{DS} voltage. This I_{DRV_UNIT} is multiplied within the Seesaw driver block to generate the current sources IS1 and IS2. In some examples, the seesaw driver circuitry 322 operates to provide I_{DRV} to turn on the transistor M1 during an on interval (e.g., a high-side on interval or a low-side on interval).

The voltage V_{GS} at the control terminal of the transistor M1 is a function of I_{DRV}, which is provided to the sixth terminal 336 of the seesaw driver circuitry 322. When V_{GS} reaches a target threshold, the transistor M1 turns on. In some examples, I_{DRV} is zero during an off interval in which the transistor M1 is off.

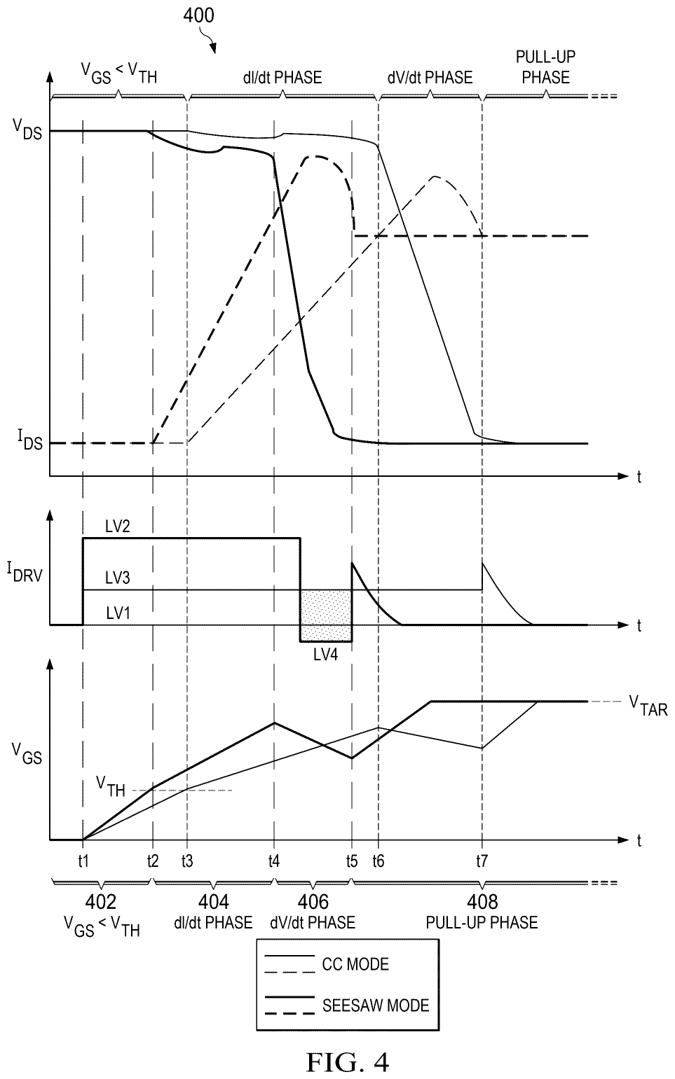

FIG. 4 is a timing diagram 400 showing different driver control modes and related waveforms. In the example of FIG. 4, constant current (CC) mode waveforms and seesaw mode waveforms for I_{DRV}, and for V_{DS}, I_{DS}, and V_{GS} of a target switch are represented. In some examples, the seesaw mode waveforms relate to the seesaw driver and control circuitry described herein (e.g., part of the seesaw driver and control circuitry 184 in FIG. 1, part of the seesaw driver and control circuitry 284 in FIG. 2, or the seesaw driver circuitry 322 in FIG. 3), while the constant current mode waveforms relates to a conventional driver and controller. In other examples, the seesaw mode waveforms and the constant current mode waveforms are different mode options of the seesaw driver and control circuitry described herein. For the seesaw mode, the driver control phases include a first control phase 402, a second control phase 404, a third control phase 406, and a fourth control phase 408. For the constant current mode, the driver control phases include a constant current phase and a pull-up phase.

At time t1, I_{DS} increases from a first level (LV1) to a second level (LV2) for the seesaw mode. For the constant current mode, I_{DS} increases from LV1 to a third level (LV3), where LV3 is less than LV2. In some examples, LV1 is zero, LV2 is approximately 1.2 A, and LV3 is approximately 0.4 A. In some examples, the first control phase 402 is referred to as a V_{GS}<V_{TH} phase of the seesaw mode, in which V_{GS} of the target switch is less than V_{TH}. Of the target switch.

With LV2 greater than LV3, V_{GS} increases faster for the seesaw mode than for the constant current mode. As a result, V_{GS} reaches V_{TH} at time t2 for the seesaw mode and reaches V_{TH} at time t3 for the constant current mode. Thus, for the seesaw mode, IDs begins to increase at time t2. For the constant current mode, IDs begins to increase at time t3. From time t2 to time t4, the seesaw mode is in the second control phase 404. In some examples, the second control phase 404 is referred to as a dl/dt phase of the seesaw mode, in which the current through target switch increases.

At time t4, V_{DS} of the target switch begins decreasing corresponding to the start of the third control phase 406 of the seesaw mode. In some examples, the third control phase 406 is referred to as a dV/dt phase of the seesaw mode, in which the Vos of the target switch decreases. During the third control phase 406, I_{DRV} is reduced from LV2 to a fourth level (LV4) below LV1. In some examples, LV4 is anywhere within the shaded area and can range from −0.2 A to 0.4 A. From time t4 to time t5, V_{GS} is reduced for the seesaw mode. For the constant current mode, V_{GS} increases linearly from time t3 to time t6. At time t5, Vos reaches a lower threshold and the seesaw mode initiates the fourth control phase 408. In some examples, the fourth control phase 408 is referred to as a pull-up phase of the seesaw mode. At time t5, I_{DRV} increases from LV4 to above LV3 and begins to decrease until settling at LV1 between time t6 and time t7. During the fourth control phase 408 of the seesaw mode, V_{GS} increases then settles to a target voltage (V_{TAR}) at which point the target switch has been fully turned on between time t6 and time t7. For the constant current mode, Vos begins dropping at time t6, and V_{GS} falls from time t6 to time t7. At time t7 for the constant current mode, Vos settles and V_{GS} begins to rise again then settles at V_{TAR} after time t7.

With the seesaw mode, I_{DRV} goes up and down at least two times (an up-down-up-down pattern) and the current levels used for I_{DRV} cause V_{GS} to teach V_{TAR} more quickly than with the constant current mode. With the constant current mode, I_{DRV} stays constant at LV3 from time t1 to time t7, then increases above LV3 before settling to LV1 (an up-up-down pattern). With the seesaw mode, V_{GS} is increased to V_{TAR} more quickly than with the constant current mode and thus losses are reduced.

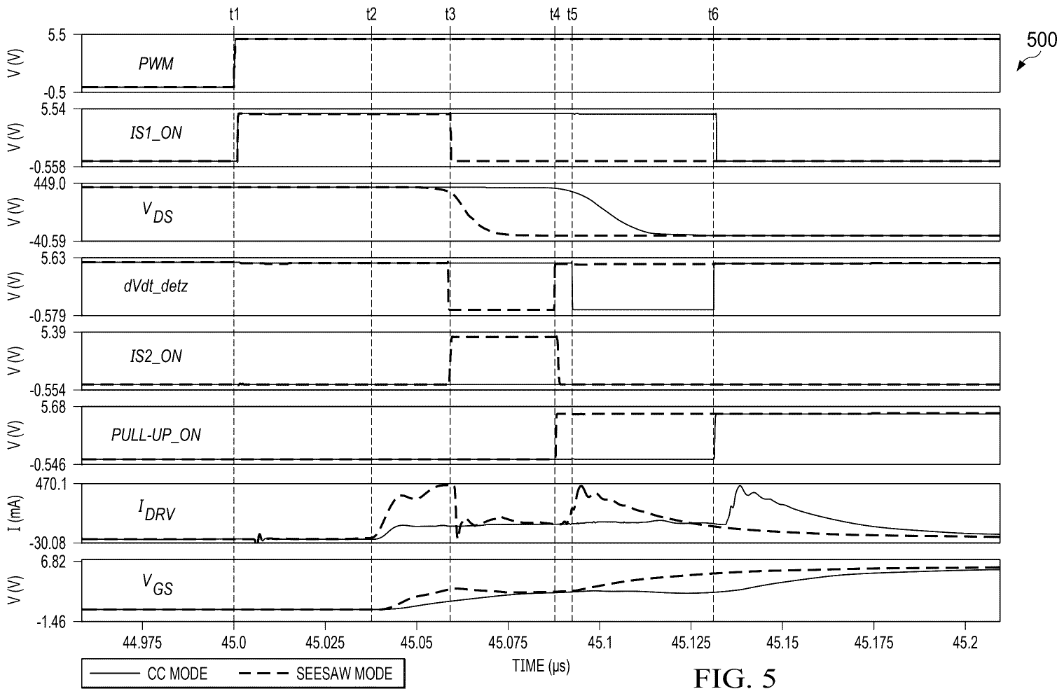

FIG. 5 is a timing diagram 500 showing example system waveforms for different modes. The different modes include the seesaw mode and the constant current mode described in FIG. 4. In some examples, the seesaw mode waveforms relate to the seesaw driver and control circuitry described herein (e.g., part of the seesaw driver and control circuitry 184 in FIG. 1, part of the seesaw driver and control circuitry 284 in FIG. 2, or the seesaw driver circuitry 322 in FIG. 3), while the continuous current mode waveforms relate to a conventional driver and controller. In other examples, the seesaw mode waveforms and the constant current mode waveforms are different mode options of the seesaw driver and control circuitry described herein. The example system waveforms in FIG. 5 include a PWM signal, a first current source on signal (IS1_ON), V_{DS}, a voltage transition detection signal (dVdt_detz), a second current source on signal (IS2_ON), a pull-up on signal (PULL-UP_ON), I_{DRV}, and V_{GS}.

For the seesaw mode, the PWM signal is asserted at time t1 responsive to control loop operations (e.g., operations of the controller 148 in FIG. 1, operations of the controller 248 in FIG. 2). Soon after time t1, IS1_ON is asserted responsive to the PWM signal being asserted. At time t2, I_{DRV} begins to increase (e.g., up to LV2 in FIG. 4). At time t3, V_{DS} begins to decrease and dVdt_detz is de-asserted. In response, seesaw mode operations include de-asserting IS1_ON, asserting IS2_ON, and decreasing I_{DRV} (e.g., down to LV3 in FIG. 4) At time t4, V_{DS} has settled and dVdt_detz is asserted. In response, IS2_ON is de-asserted and PULL-UP_ON is asserted. In response, I_{DRV} increases (e.g., to approximately LV2 in FIG. 4) then decreases and settles (e.g., to approximately LV1 in FIG. 4). With the seesaw mode operations, V_{GS} increases after time t2 and settles at a target value (e.g., V_{TAR} in FIG. 4) at about time t6.

For the constant current mode, the PWM signal is asserted at time t1. Soon after time t1, IS1_ON is asserted responsive to the PWM signal being asserted. At time t2, I_{DRV} begins to increase (e.g., to approximately LV3 in FIG. 4). At time t5, V_{DS} begins to decrease and dVdt_detz is de-asserted. At time t6, V_{DS} has settled, dVdt_detz is asserted, and PULL-UP_ON is asserted. In response, I_{DRV} increases (e.g., to approximately LV2 in FIG. 4) then decreases and settles (e.g., to approximately LV1 in FIG. 4). With the constant current mode operations, V_{GS} increases after time t2 and settles at a target value (e.g., V_{TAR} in FIG. 4) after time t6.

With the seesaw mode, I_{DRV} goes up and down at least two times (an up-down-up-down pattern) and the current levels used for I_{DRV} cause V_{GS} to teach V_{TAR} more quickly than with the constant current mode. With the constant current mode, I_{DRV} stays constant (e.g., at approximately LV3 in FIG. 4) from approximately time t2 to time t6, then increases (e.g., to approximately LV2 in FIG. 4) before settling to approximately LV1 in FIG. 4 (an up-up-down pattern). With the seesaw mode, V_{GS} is increased to V_{TAR} more quickly than with the constant current mode and thus losses are reduced.

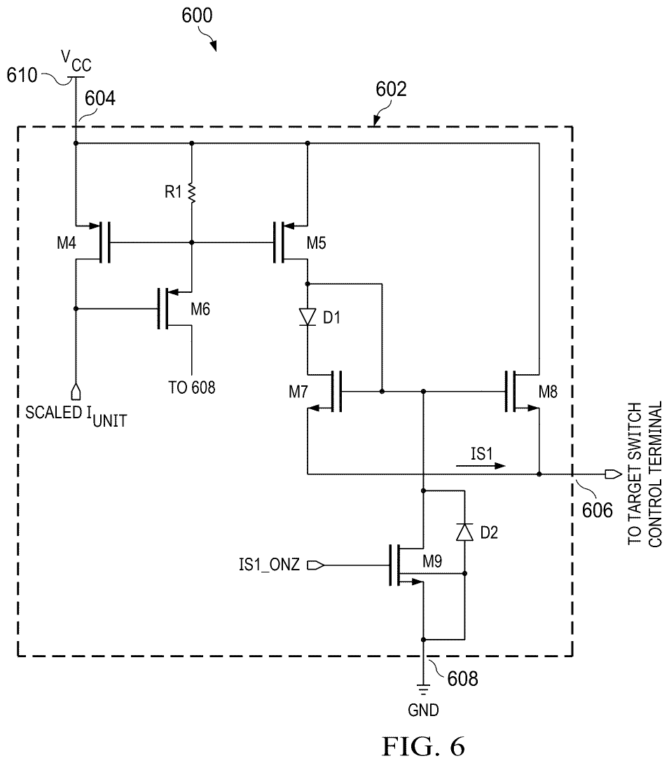

FIG. 6 is a schematic diagram 600 showing an example first current source 602 of a seesaw driver (e.g., the seesaw driver and control circuitry 184 in FIG. 1, the seesaw driver and control circuitry 284 in FIG. 2, or the seesaw driver circuitry 322 in FIG. 3). The first current source 602 is an example of the first current source 338 in FIG. 3. In the example of FIG. 6, the first current source 602 has a first terminal 604, a second terminal 606, and a third terminal 608. The first current source includes a resistor R1, diodes D1 and D2, and transistors M4 to M9 in the arrangement shown. In some examples, the diode D2 may be part of the transistor M9. The resistor R1 has a first terminal and a second terminal. Each of the diodes D1 and D2 has a respective anode terminal and a respective cathode terminal. Each of the transistors M4 to M8 has a respective first terminal, a respective second terminal, and a respective control terminal. The transistor M9 has a first terminal, a second terminal, a control terminal, and a base terminal. In the example of FIG. 6, the transistors M4 to M6 are PMOS transistors, and the transistors M7 to M9 are NMOS transistors.

In the example of FIG. 6, the first terminal 604 of the first current source 602 is coupled to a power supply (V_{CC}) terminal 610. The second terminal 606 of the first current source 602 is coupled to a target switch control terminal (e.g., the control terminal of the HS switch 120 in FIG. 1, the control terminal of the LS switch 128 in FIG. 1, the control terminal of the first switch 228 in FIG. 2, the control terminal of the second switch 236 in FIG. 2, or the control terminal of the transistor M1 in FIG. 3). The third terminal 608 of the first current source 602 is coupled to ground or a ground terminal.

The first terminals of the resistor R1, and the transistors M4, M5, and M8 are coupled to the first terminal 604 of the first current source 602. The second terminal of the transistor M4 is coupled to the control terminal of the transistor M6. The second terminal of the resistor R1 is coupled to the control terminals of the transistors M4 and M5 and to the first terminal of the transistor M6. The second terminal of the transistor M6 is coupled to the third terminal 608 of the first current source 602. The second terminal of the transistor M5 is coupled to the anode terminal of the diode D1, the control terminals of the transistor M7 and M8, the first terminal of the transistor M9, and the cathode terminal of the diode D2. The cathode terminal of the diode D1 is coupled to the first terminal of the transistor M7. The second terminal of the transistors M7 and M8 are coupled to the second terminal 606 of the first current source 602. The control terminal of the transistor M9 is coupled to a controller (not shown) and a receives a control signal (IS1_ONZ, where IS1_ONZ is the inverse of IS1_ON). The body terminal of the transistor M9 is coupled to the anode terminal of the diode D2. The second terminal of the transistor M9 is coupled to the third terminal 608 of the first current source 602.

The first current source 602 is configurable to: receive V_{CC} at the first terminal 604; and provide IS1 at the second terminal 606 responsive to V_{CC} and current control operations of the transistors M4 to M8, the resistor R1, and the diode D1. In some examples, the transistors M4, M5, and M7 performing sourcing current mirror operations to mirror a current (e.g., a scaled I_{UNIT}), resulting in IS1 being sourced to the second terminal 606 of the first current source 602. In some examples, I_{UNIT} is 20 uA, and the scaling is 20×. In some examples, the first current source 602 is disabled when IS1_ONZ is asserted to the control terminal of the transistor M9.

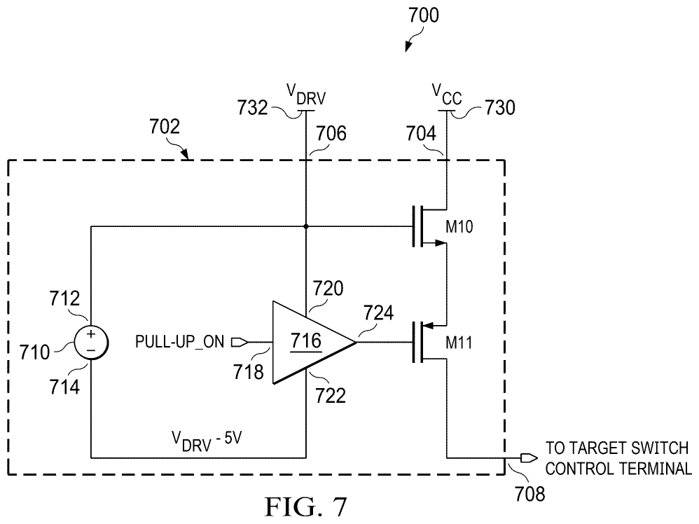

FIG. 7 is a schematic diagram 700 showing an example switch circuit 702 of a seesaw driver (e.g., the seesaw driver and control circuitry 184 in FIG. 1, the seesaw driver and control circuitry 284 in FIG. 2, or the seesaw driver circuitry 322 in FIG. 3). In some examples, the switch circuit 702 may replace the transistor M2 in FIG. 3. As shown, the switch circuit 702 has a first terminal 704, a second terminal 706, and a third terminal 708. In some examples, the first terminal 704 is coupled to a power supply (VCC) terminal 730, and the second terminal 706 is coupled to a drive voltage (V_{DRV}) terminal 732. The switch circuit 702 includes a voltage source 710, a driver 716, and transistors M10 and M11. The voltage source 710 has a first terminal 712 and a second terminal 714. The driver 716 has a first terminal 718, a second terminal 720, a third terminal 722, and a fourth terminal 724. Each of the transistors M10 and M11 has a respective first terminal, a respective second terminal, and a respective control terminal. In the example of FIG. 7, the transistor M10 is an NMOS transistor, and the transistor M11 is a PMOS transistor.

The first terminal 704 of the switch circuit 702 is coupled to a power supply (V_{CC}) terminal 730 and the first terminal of the transistor M10. The second terminal 706 of the switch circuit 702 is coupled to a drive voltage (V_{DRV}) terminal 732, the control terminal of the transistor M10, the first terminal 712 of the voltage source 710, and the second terminal 720 of the driver 716. The third terminal 708 of the switch circuit 702 is coupled to a target switch control terminal (e.g., the control terminal of the HS switch 120 in FIG. 1, the control terminal of the LS switch 128 in FIG. 1, the control terminal of the first switch 228 in FIG. 2, the control terminal of the second switch 236 in FIG. 2, or the control terminal of the transistor M1 in FIG. 3) and the second terminal of the transistor M11. The second terminal of the transistor M10 is coupled to the first terminal of the transistor M11. The second terminal 714 of the voltage source 710 is coupled to the third terminal 722 of the driver 716. In some examples, the third terminal 722 of the driver 716 and the control terminal of the transistor M10 receive V_{DRV}, while the third terminal 722 of the driver 716 receives V_{DRV}−5V. The fourth terminal 724 of the driver 716 is coupled to the control terminal of the transistor M11.

In some examples, the switch circuit 702 is configurable to: receive V_{CC} at the first terminal 704; receive V_{DRV} at the second terminal 706; and provide a target voltage (e.g., V_{TAR}) at the third terminal 708 responsive to V_{CC}, V_{DRV}, and the operations of the voltage source 710, the transistors M10 and M11, and the driver 716. In some examples, when PULL-UP_ON is asserted, the switch circuit 702 provides V_{TAR} at the third terminal 708. When PULL-UP_ON is de-asserted, the switch circuit 702 is turned off.

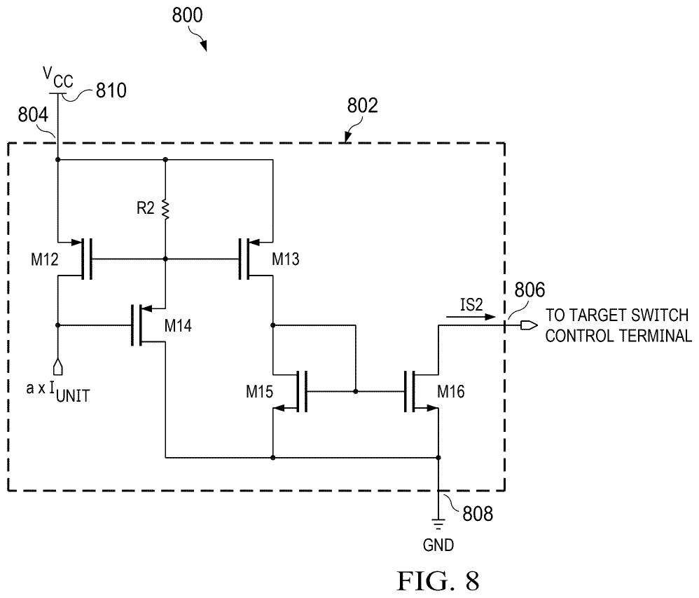

FIG. 8 is a schematic diagram 800 showing an example second current source 802 of a seesaw driver (e.g., the seesaw driver and control circuitry 184 in FIG. 1, the seesaw driver and control circuitry 284 in FIG. 2, or the seesaw driver circuitry 322 in FIG. 3). The second current source 802 is an example of the second current source 344 in FIG. 3. In the example of FIG. 8, the second current source 800 has a first terminal 804, a second terminal 806, and a third terminal 808. The second current source 802 includes a resistor R2 and transistors M12 to M16 in the arrangement shown. The resistor R2 has a first terminal and a second terminal. Each of the transistors M12 to M16 has a respective first terminal, a respective second terminal, and a respective control terminal. In the example of FIG. 8, the transistors M12 to M14 are PMOS transistors, and the transistors M15 and M16 are NMOS transistors.

The first terminal 804 of the second current source 802 is coupled to a power supply (V_{CC}) terminal 810 and the first terminals of the resistor R2, and the transistors M12 and M13. The second terminal 806 of second current source 802 is coupled to a target switch control terminal (e.g., the control terminal of the HS switch 120 in FIG. 1, the control terminal of the LS switch 128 in FIG. 1, the control terminal of the first switch 228 in FIG. 2, the control terminal of the second switch 236 in FIG. 2, or the control terminal of the transistor M1 in FIG. 3) and a first terminal of the transistor M16. The third terminal 808 of the second current source 802 is coupled to ground or a ground terminal. The second terminal of the transistor M12 is coupled to the control terminal of the transistor M14. The second terminal of the resistor R2 is coupled to the first terminal of the transistor M14 and the control terminals of the transistors M12 and M13. The second terminal of the transistor M14 is coupled to the third terminal 808. The second terminal of the transistor M13 is coupled to the first terminal of the transistor M15 and the control terminals of the transistors M15 and M16. The second terminals of the transistors M15 and M16 are coupled to the third terminal 808 of the second current source 802.

The second current source 802 is configurable to: receive V_{CC} at the first terminal 604; and sink IS2 from the second terminal 806 responsive to V_{CC} and current control operations of the transistors M12 to M16 and the resistor R2. In some examples, the transistors M12, M13, M15, and M16 perform sinking current mirror operations based on “a x I_{UNIT}” at the second terminal of the transistor M12, where “a” is a scaling factor. The sinking current mirror operations result in IS2 being sunk from the second terminal 606 of the first current source 602. In some examples, I_{UNIT} is 20 uA and the scaling “a” is 20×.

In a seesaw mode, I_{DRV} during a second control phase (e.g., the second control phase 404 or dV/dt phase in FIG. 4 can be: equal to that of constant current mode; lower than the constant current mode but positive; or can be a sinking current which takes charge out of target switch gate. In some examples, sinking current mirrors of the second current source 802 are designed to support the second control phase along with the constant current sourcing current mirrors. In some examples, drain extended NMOS (DENMOS) transistors are used rather than laterally-diffused metal-oxide semiconductor (LDMOS) for the final stage current mirror (e.g., transistors M15 and M16) due to better channel length modulation characteristics over a supply voltage (V_{CC}) that varies (e.g., from 8V to 26V) and better matching. Use of DENMOS carries a slight area penalty but is insignificant compared to overall die size. Unlike prior GaN drivers which use an internal LDO to drive a GaN gate (e.g., 180 mOhm GaN transistor), a seesaw driver supports large eGaN transistors (e.g., a 150 mOhm to 12 mOhm GaN transistor).

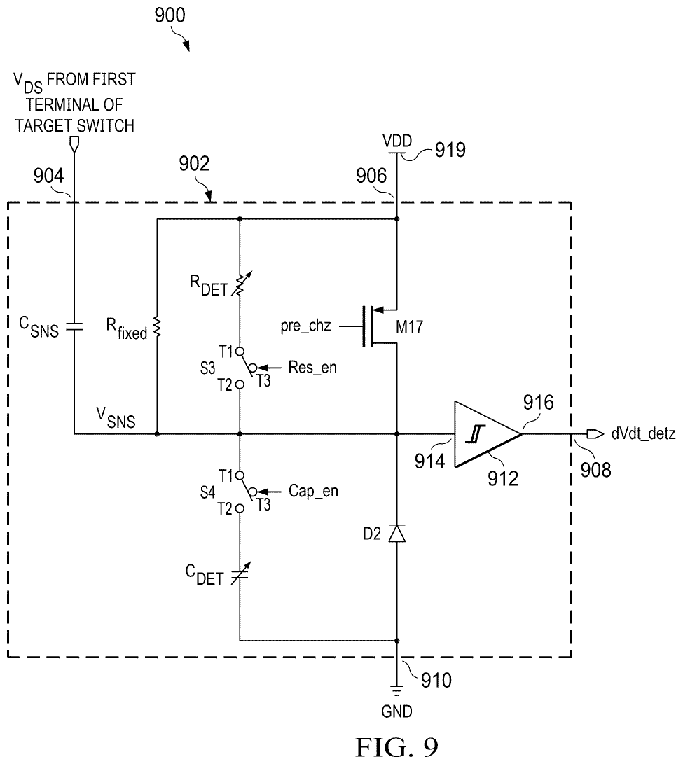

FIG. 9 is a schematic diagram 900 showing example voltage transition detection circuitry 902 of a seesaw driver (e.g., part of the seesaw driver and control circuitry 184 in FIG. 1, part of the seesaw driver and control circuitry 284 in FIG. 2, or the seesaw driver circuitry 322 in FIG. 3). The voltage transition detection circuitry 902 is an example of the voltage transition detection circuitry 364 in FIG. 3. In the example of FIG. 9, the voltage transition detection circuitry 902 has a first terminal 904, a second terminal 906, a third terminal 908, and a fourth terminal 910. The voltage transition detection circuitry 902 includes a capacitor C_{SNS}, a variable capacitor (varactor) C_{DET}, a variable resistor R_{DET}, a resistor R_{fixed}, switches S3 and S4, a transistor M17, a diode D2, and a Schmitt trigger 912. The capacitor C_{SNS} has a first terminal and a second terminal. The variable capacitor C_{DET} has a first terminal and a second terminal. The variable resistor R_{DET} has a first terminal and a second terminal. The resistor R_{fixed} has a first terminal and a second terminal. Each of the switches S3 and S4 has a respective first terminal T1, a respective second terminal T2, and a respective control terminal T3. The transistor M17 has a first terminal, a second terminal, and a control terminal. The diode D2 has an anode terminal and a cathode terminal. The Schmitt trigger 912 has a first terminal 914 and a second terminal 916.

The first terminal 904 of the voltage transition detection circuitry 902 is coupled to a first terminal of a target switch (e.g., the first terminal of the HS switch 120 in FIG. 1, the first terminal of the LS switch 128 in FIG. 1, the first terminal of the first switch 228 in FIG. 2, the first terminal of the second switch 236 in FIG. 2, or the first terminal of the transistor M1 in FIG. 3) and the first terminal of the capacitor C_{SNS}. The second terminal 906 of the voltage transition detection circuitry 902 is coupled to a power supply (VDD) terminal 919, the first terminal of the transistor M17, the first terminal of the variable resistor R_{DET}, and the first terminal of the resistor R_{fixed}. The third terminal 908 of the voltage transition detection circuitry 902 is coupled to the second terminal 916 of the Schmitt trigger 912. The fourth terminal 910 of the voltage transition detection circuitry 902 is coupled to ground or a ground terminal.

The second terminal of the capacitor C_{SNS} is coupled to the second terminal of the resistor R_{fixed}, second terminal T2 of the switch S3, the first terminal T1 of the switch S4, the second terminal of the transistor M17, the cathode terminal of the diode D2, and the first terminal 914 of the Schmitt trigger 912. With R_{fixed}, the Vsns node is held to VDD so that any random low frequency noise coupling through Csns does not falsely trip the Schmitt trigger 912. The control terminal of the transistor M17 receives a narrow control signal pulse pre_chz which is generated immediately after Cap_en goes high. This pulse has an on-time of roughly about 2 ns. The second terminal of the variable resistor R_{DET} is coupled to the first terminal T1 of the switch S3. The control terminal of the switch S3 receives a control signal Res_en. The second terminal T2 of the switch S4 is coupled to the first terminal of the variable capacitor C_{DET}. The control terminal of the switch S4 receives a control signal Cap_en. The second terminal of the variable capacitor C_{DET} and the anode terminal of the diode D2 are coupled to the fourth terminal 910 of the voltage transition detection circuitry 902.

The voltage transition detection circuitry 902 is configurable to: receive V_{DS} from a first terminal of a target switch at the first terminal 904 of the voltage transition detection circuitry 902; receive VDD at the second terminal 906 of the voltage transition detection circuitry 902; and provide dVdt_detz at the third terminal 908 of the voltage transition detection circuitry 902 responsive to V_{DS}, VDD, and the operations of the capacitor C_{SNS}, the variable capacitor C_{DET}, the variable resistor R_{DET}, the switches S3 and S4, the transistor M17, the diode D2, and the Schmitt trigger 912. In some examples, Res_en and Cap_en are generated within the voltage transition detection circuitry 364 based on switch control signal (e.g., SW1_CS) and the dVdt_detz signal. During voltage transition detection operations Res_en closes the switch S3 responsive to the dVdt_detz signal being low. Res_en opens the switch S3 responsive to the switch control signal (e.g., SW1_CS) being low. Cap_en closes the switch S4 responsive to the switch control signal (e.g., SW1_CS) being low. Cap_en opens the switch S4 responsive to dVdt_detz signal being low.

In some examples, a voltage transition start involves detecting a change in V_{DS} based on a capacitor divider formed by C_{SNS}, C_{DET}, and the switch S4. A voltage transition end involves detecting voltage transition below a threshold based on R_{DET} and C_{DET}. In some examples, the voltage transition detection circuitry 902 includes a high-voltage eGaN capacitor coupled to the first terminal of the target switch. In the example of FIG. 9, either the variable capacitor C_{DET} or the variable resistor R_{DET} is enabled at any given point in time to ensure accurate detection. In some examples, programmable start and end points are based on slew-rate settings such as one-time programmable (OTP) setting. In the example of FIG. 9, the capacitor C_{SNS} scales up with slew rate and RSNS scales down with slew rate. In some examples, a voltage transition start (VTS) is given as:

$$VTS \approx ( VDD - {V}_{TRIP ( low )} ) \frac{{C}_{SNS} + {C}_{DET}}{{C}_{SNS}} , \qquad Equation ( 1 )$$

where V_{TRIP(low)} refers to the trip voltage of the Schmitt trigger 912 to provide a low output. In some examples, a voltage transition start (VTS) is given as:

$$VTE \approx \frac{( VDD - {V}_{TRIP ( high )} )}{{R}_{DET} * {C}_{SNS}} , \qquad Equation ( 2 )$$

where V_{TRIP(high)} refers to the trip voltage of the Schmitt trigger 912 to provide a high output.

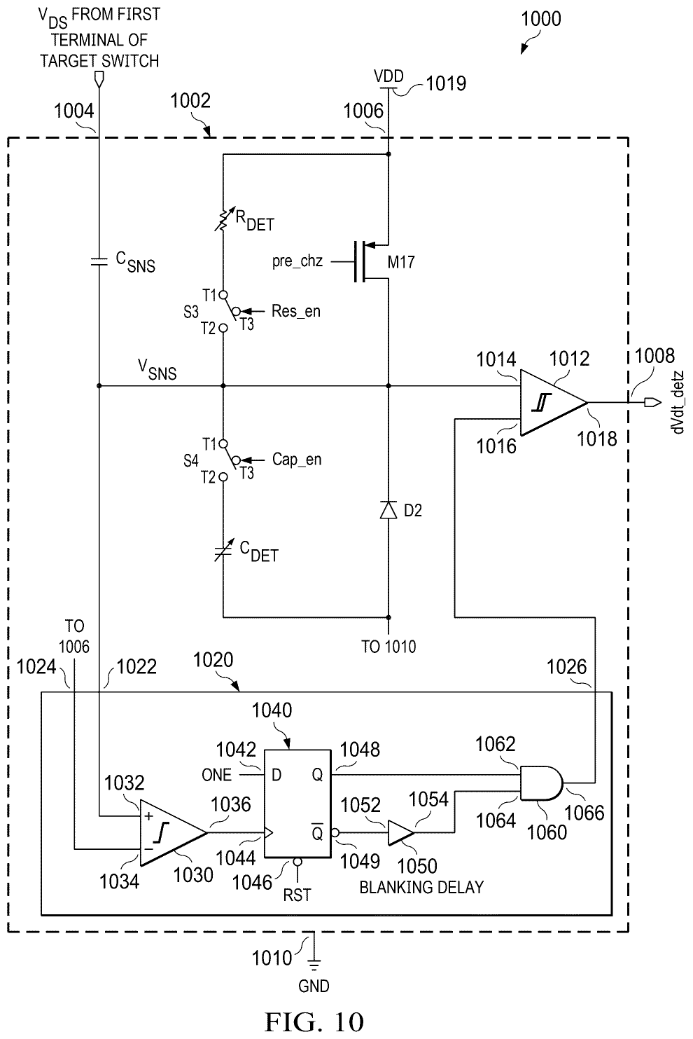

FIG. 10 is a schematic diagram 1000 showing example voltage transition detection circuitry 1002 of a seesaw driver (e.g., the seesaw driver and control circuitry 184 in FIG. 1, the seesaw driver and control circuitry 284 in FIG. 2, or the seesaw driver circuitry 322 in FIG. 3). The voltage transition detection circuitry 1002 is an example of the voltage transition detection circuitry 364 in FIG. 3. In the example of FIG. 10, the voltage transition detection circuitry 1002 has a first terminal 1004, a second terminal 1006, a third terminal 1008, and a fourth terminal 1010. The voltage transition detection circuitry 1002 includes the capacitor C_{SNS}, the variable capacitor (varactor) C_{DET}, the variable resistor R_{DET}, the switches S3 and S4, the transistor M17, the diode D2, a Schmitt trigger 1012, and blanking delay circuitry 1020. The blanking delay circuitry 1020 has a first terminal 1022, a second terminal 1024, and a third terminal 1026. In the example of FIG. 10, the blanking delay circuitry 1020 includes a comparator 1030, a D flip-flop 1040, a delay circuit 1050, and an AND gate 1060.

The capacitor C_{SNS} has a first terminal and a second terminal. The variable capacitor C_{DET} has a first terminal and a second terminal. The variable resistor R_{DET} has a first terminal and a second terminal. Each of the switches S3 and S4 has a respective first terminal T1, a respective second terminal T2, and a respective control terminal T3. The transistor M17 has a first terminal, a second terminal, and a control terminal. The diode D2 has an anode terminal and a cathode terminal. The Schmitt trigger 1020 has a first terminal 1014, a second terminal 1016, and a third terminal 1018. The comparator 1030 has a first terminal 1032, a second terminal 1034, and a third terminal 1036. The D flip-flop 1040 has a first terminal 1042, a second terminal 1044, a third terminal 1046, a fourth terminal 1048, and a fifth terminal 1049. The delay circuit 1050 has a first terminal 1052 and a second terminal 1054. The AND gate 1060 has a first terminal 1062, a second terminal 1064, and a third terminal 1066.

The first terminal 1004 of the voltage transition detection circuitry 1002 is coupled to a first terminal of a target switch (e.g., the first terminal of the HS switch 120 in FIG. 1, the first terminal of the LS switch 128 in FIG. 1, the first terminal of the first switch 228 in FIG. 2, the first terminal of the second switch 236 in FIG. 2, or the first terminal of the transistor M1 in FIG. 3) and the first terminal of the capacitor C_{SNS}. The second terminal 1006 of the voltage transition detection circuitry 1002 is coupled to a power supply (VDD) terminal 1019, the first terminal of the transistor M17, and the first terminal of the variable resistor R_{DET}. The third terminal 1008 of the voltage transition detection circuitry 1002 is coupled to the third terminal 1018 of the Schmitt trigger 1012. The fourth terminal 1010 of the voltage transition detection circuitry 1002 is coupled to ground or a ground terminal.

The second terminal of the capacitor C_{SNS} is coupled to the second terminal T2 of the switch S3, the first terminal T1 of the switch S4, the second terminal of the transistor M17, the cathode terminal of the diode D2, the first terminal 1014 of the Schmitt trigger 1012, and the first terminal 1022 of the blanking delay circuitry 1020 The control terminal of the transistor M17 receives a narrow control signal pulse pre_chz which is generated immediately after Cap_en goes high. This pulse has an on-time of roughly about 2 ns. The second terminal of the variable resistor R_{DET} is coupled to the first terminal T1 of the switch S3. The control terminal of the switch S3 receives a control signal Res_en. The second terminal T2 of the switch S4 is coupled to the first terminal of the variable capacitor C_{DET}. The control terminal of the switch S4 receives a control signal Cap_en. The second terminal of the variable capacitor C_{DET} and the anode terminal of the diode D2 are coupled to the fourth terminal 1010 of the voltage transition detection circuitry 1002.

The second terminal 1024 of the blanking delay circuitry 1020 is coupled to the second terminal 1006 of the blanking delay circuitry 1020. The third terminal 1026 of the blanking delay circuitry 1020 is coupled to the second terminal 1016 of the Schmitt trigger 1012. The first terminal 1032 of the comparator 1030 is coupled to the first terminal 1022 of the blanking delay circuitry 1020. The second terminal 1034 of the comparator is coupled to the second terminal 1024 of the blanking delay circuitry 1020. The third terminal 1036 of the comparator 1030 is coupled to the second terminal 1044 of the D flip-flop 1040. The first terminal 1042 of the D flip-flop 1040 receives a signal (ONE, which is a logical “1”). The third terminal 1046 of the D flip-flop 1040 receives a reset signal (RST). The fourth terminal 1048 of the D flip-flop 1040 is coupled to the first terminal 1062 of the AND gate 1060. The fifth terminal 1049 of the D flip-flop 1040 is coupled to the first terminal 1052 of the delay circuit 1050. The second terminal 1054 of the delay circuit 1050 is coupled to the second terminal 1064 of the AND gate 1060.

The voltage transition detection circuitry 1002 is configurable to: receive V_{DS} from a first terminal of a target switch at the first terminal 1004 of the voltage transition detection circuitry 1002; receive VDD at the second terminal 1006 of the voltage transition detection circuitry 1002; and provide dVdt_detz at the third terminal 1008 of the voltage transition detection circuitry 1002 responsive to V_{DS}, VDD, and the operations of the capacitor C_{SNS}, the variable capacitor C_{DET}, the variable resistor R_{DET}, the switches S3 and S4, the transistor M17, the diode D2, the Schmitt trigger 1012, and the blanking delay circuitry 1020. In some examples, a voltage transition start involves detecting a change in V_{DS} based on a capacitor divider formed by C_{SNS}, C_{DET}, and the switch S4. A voltage transition end involves detecting voltage transition below a threshold based on R_{DET} and C_{DET}. In some examples, the voltage transition detection circuitry 1002 includes a high-voltage eGaN capacitor coupled to the first terminal of the target switch. In the example of FIG. 10, either the variable capacitor C_{DET} or the variable resistor R_{DET} is enabled at any given point in time to ensure accurate detection. In some examples, programmable start and end points are based on slew-rate settings such as one-time programmable (OTP) settings. In the example of FIG. 10, the sense capacitance (e.g., C_{SNS} and/or C_{DET}) scales up with slew rate and the sense resistance (e.g., R_{DET}) scales down with slew rate. In some examples, VTS and VTE of the voltage transition detection circuitry 1002 are given with Equations 1 and 2.

With the blanking delay circuitry 1020, a rising edge in V_{DS} triggers a blanking interval. During the blanking interval, the Schmitt trigger 1012 is disabled by the blanking delay circuitry 1020. After the blanking interval, a falling edge in V_{DS} is detected by the voltage transition detection circuitry 1002 and results in dVdt_detz being de-asserted at the third terminal 1008 of the voltage transition detection circuitry 1002.

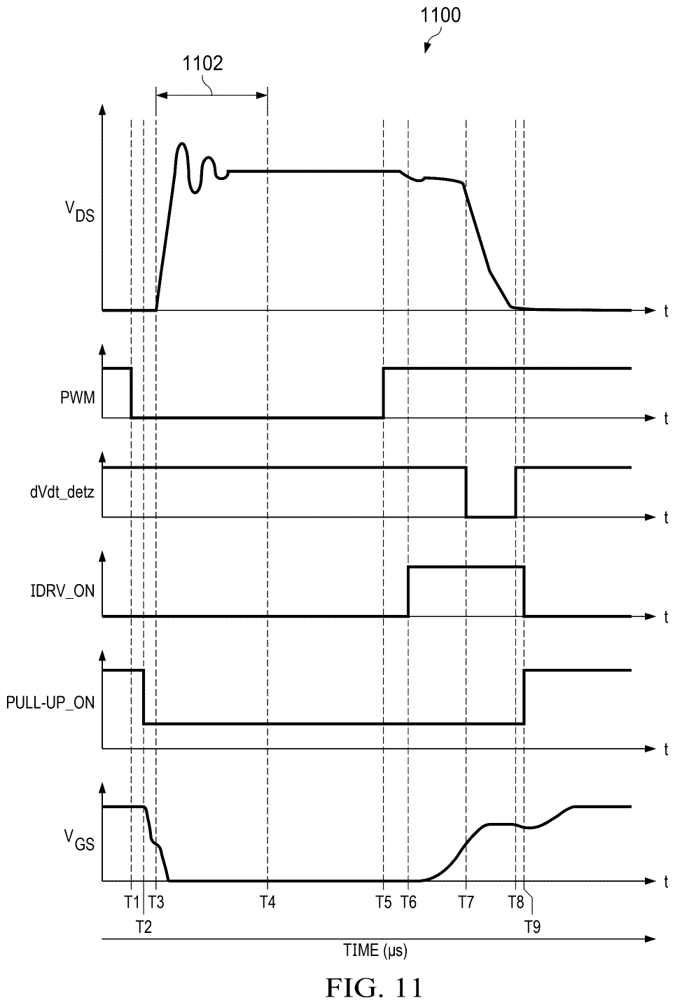

FIG. 11 is a timing diagram 1100 showing example system signals for a hard-switching event. In the example of FIG. 11, the system signals include V_{GS}, a PWM signal, dVdt_detz, an I_{DRV} on signal (IDRV_ON), PULL-UP_ON, and V_{GS}. At time t1, the PWM signal is de-asserted. In response, PULL-UP_ON is de-asserted at time t2, a related target switch is turned off, and V_{GS} begins to drop. V_{DS} begins to rise at time t3. From time t3 to time t4, a blanking interval 1102 (e.g., provided by the blanking delay circuitry 1020 in FIG. 10) is used so that voltage transition detection (related to dVdt_detz) is not triggered by V_{DS} ripple. At time t5, the PWM signal is asserted. At time t6, IDRV_ON is asserted responsive to the PWM signal being asserted previously and V_{GS} begins to rise until settling after time T9. At time t7, V_{DS} begins to decrease outside the blanking interval 1102 and dVdt_detz is de-asserted. At time t8, V_{DS} transition is complete (V_{DS} has settled) and dVdt_detz is asserted. At time t9, IDRV_ON is de-asserted and PULL-UP_ON is asserted. When the PWM signal is asserted before a V_{DS} transition, a hard-switching event is indicated. In response to a hard-switching event, a seesaw driver may perform seesaw mode operations to turn on a target switch.

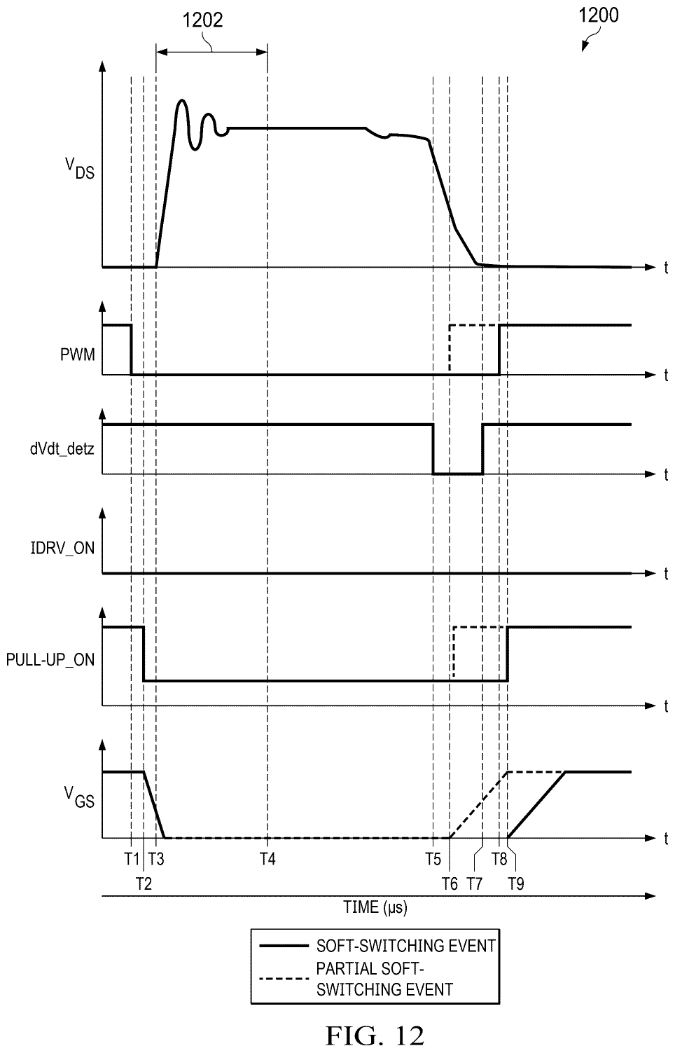

FIG. 12 is a timing diagram 1200 showing example system signals for a soft-switching event. In the example of FIG. 12, the system signals include V_{DS}, the PWM signal, dVdt_detz, IDRV_ON, PULL-UP_ON, and V_{GS}. At time T1, the PWM is de-asserted. In response, PULL-UP_ON is de-asserted at time T2, a related target switch is turned off, and V_{GS} begins to fall. Vos begins to rise at time T3. From time T3 to time T4, a blanking interval 1202 (e.g., provided by the blanking delay circuitry 1020 in FIG. 10) is used so that voltage transition detection (related to dVdt_detz) is not triggered by Vos ripple. At time T5, Vos begins to decrease outside the blanking interval 1202 and dVdt_detz is de-asserted. At time T7, Vos transition is complete (Vos has settled) and dVdt_detz is asserted. At time T8, the PWM signal is asserted. In response, PULL-UP_ON is asserted at time T9 and V_{GS} beings to rise until settling at a target V_{GS}.

In some scenarios, the PWM signal may be asserted while Vos is transitioning from high-to-low (e.g., represented by the dashed line portion of the PWM signal asserted at time T6). In such case, a partial soft-switching event is triggered. For a partial soft-switching event, PULL-UP_ON is asserted soon after PWM is asserted (represented by the dashed line portion of PULL-UP_ON) and V_{GS} begins to rise. In response to either a partial soft-switching event or a soft-switching event, seesaw driver and control circuitry may directly transition to pull-up mode operations to turn on a target switch. In the example of FIG. 12, use of a pull-up mode response for a partial soft-switching event or a soft-switching event avoids V_{GS} overshoot, which is an improvement compared to use of a constant current mode.

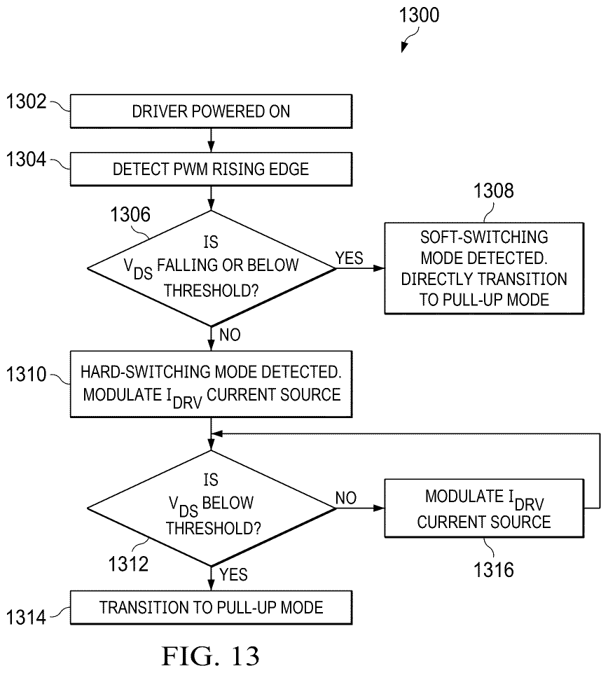

FIG. 13 is a flowchart showing an example seesaw driver control method 1300. In some examples, the seesaw driver control method 1300 is performed by control circuitry of the seesaw driver and control circuitry 184 of FIG. 1, the seesaw driver and control circuitry 284 of FIG. 2, the control circuitry 350 in FIG. 3, or the control logic 370 in FIG. 3. As shown, the seesaw driver control method 1300 includes the seesaw driver being powered on at block 1302. At block 1304, a PWM rising edge is detected. If Vos (of a target switch) is falling or is below a threshold (block 1306), a soft-switching event is detected and the seesaw driver control method 1300 directly transitions to a pull-up mode at block 1308. If Vos (of a target switch) is not falling or is not below a threshold (block 1306), a hard-switching event is detected and the seesaw driver control method 1300 modulates I_{DRV} current source(s) at block 1310. In some examples, the I_{DRV} current source(s) are modulated based on a seesaw mode or seesaw I_{DRV} modulation at block 1310. If Vos is below a threshold (block 1312), the seesaw driver control method 1300 transitions to the pull-up mode at block 1314. If Vos is not below a threshold (block 1312), the seesaw driver control method 1300 modulates the I_{DRV} current source(s) at block 1316 and returns to block 1312.

In some examples, a circuit (e.g., the controller 148 in FIG. 1, the controller 248 in FIG. 2, circuitry of the first die 302 and/or the second die 312 in FIG. 3, or related circuits in FIGS. 6 to 10) includes: a transistor (e.g., the HS switch 120 in FIG. 1, the LS switch 128 in FIG. 1, the first switch 228 in FIG. 2, the second switch 236 in FIG. 2, the transistor M1 in FIG. 3); driver circuitry (e.g., the seesaw driver and control circuitry 184 in FIG. 1, the seesaw driver and control circuitry 284 in FIG. 2, the seesaw driver circuitry 322 in FIG. 3, or related circuits in FIGS. 6 to 10); and control circuitry (e.g., the control circuitry 350 in FIG. 3). The transistor has a first terminal, a second terminal, and a control terminal. The driver circuitry has a set of first terminals (e.g., the set of first terminal 326), a second terminal (e.g., the second terminal 328 in FIG. 3), and a third terminal (e.g., the sixth terminal 336 in FIG. 3). The control circuitry has a first terminal (e.g., the first terminal 352 in FIG. 3) and a set of second terminal (e.g., the set of second terminals 354 in FIG. 3). The first terminal of the control circuitry is coupled to the first terminal of the transistor. Terminals of the set of second terminals of the control circuitry are coupled to respective terminals of the set of first terminals of the driver circuitry. The control circuitry is configurable to: receive a voltage (e.g., Vos of the target switch herein) at the first terminal of the control circuitry; receive a first control signal (e.g., the PWM signal herein); identify a switching event for the transistor as a soft-switching event responsive to the voltage and the first control signal; and, in response to identifying the switching event for the transistor as a soft-switching event, adjust second control signals at the set of second terminals of the control circuitry.

In some examples, the control circuitry is configurable to identify the switching event for the transistor as a soft-switching event responsive to the voltage decreasing before or while the first control signal transitions to an on-state. In some examples, the driver circuitry is configurable to modulate current during different control phases to adjust voltage at the third terminal of the driver circuitry responsive to the second control signals. In some examples, the voltage (e.g., Vos herein) is a first voltage and the different control phases include: a first control phase (e.g., the first control phase 402 in FIG. 4) in which a second voltage (e.g., V_{GS} herein) at the control terminal of the transistor is less than a first threshold (e.g., V_{TH} herein); a second control phase (e.g., the second control phase 404 in FIG. 4) in which current through the transistor increases; a third control phase (e.g., the third control phase 406 in FIG. 4) in which the first voltage is decreasing; and a fourth control phase (e.g., the fourth control phase 408 in FIG. 4) initiated after the first voltage drops below a second threshold (e.g., a threshold indicating V_{DS} has settled at a low value)

In some examples, the modulated current includes: a fixed positive current level (e.g., I_{DRV} during the first and second control phases 402 and 404 in FIG. 4, or IS1 herein) during some of the first control phase and during the second control phase; a negative current level (e.g., I_{DRV} during at least part of the third control phase 406 in FIG. 4, or IS2 herein) during the third control phase; and a negative ramp then zero current level (e.g., the I_{DRV} during the fourth control phase 408 in FIG. 4) during the fourth control phase. In some examples, the fourth control phase is a pull-up phase that switches from current modulation to a pull-up voltage at the second terminal of the driver circuitry to control voltage at the third terminal of the driver circuitry.

In some examples, the circuit is part of an IC package (e.g., an IC package that includes the first die 302 and the second die 312 in FIG. 3) that includes a die (e.g., a die that combines the components of the first die 302 and the second die 312 in FIG. 3) with the transistor and the driver circuitry. In some examples, the circuit is part of an integrated circuit package that includes a first die (e.g., the first die 302 in FIG. 3) with the transistor and a second die (e.g., the second die 312 in FIG. 3) with the driver circuitry. In some examples, the transistor is a GaN transistor.

In some examples, an IC package (e.g., an IC package with the controller 148 in FIG. 1, the controller 248 in FIG. 2, circuitry of the first die 302 and/or the second die 312 in FIG. 3, or related circuits in FIGS. 6 to 10) includes: a GaN transistor (e.g., the HS switch 120 in FIG. 1, the LS switch 128 in FIG. 1, the first switch 228 in FIG. 2, the second switch 236 in FIG. 2, the transistor M1 in FIG. 3) having a first terminal, a second terminal, and a control terminal; a first current source (e.g., the first current source 338 in FIG. 3 or the first current source 602 in FIG. 6) having a first terminal and a second terminal; a first switch (e.g., the switch S1 in FIG. 3) coupled between the second terminal of the first current source and the control terminal of the transistor; a second current source (e.g., the second current source 344 in FIG. 3, or the second current source in FIG. 8) having a first terminal and a second terminal; and a second switch (e.g., the switch S2 in FIG. 3) between the second terminal of the second current source and the control terminal of the transistor.

In some examples, the IC package includes control circuitry (e.g., the control circuitry 350 in FIG. 3) coupled to the control terminal of the first switch and the control terminal of the second switch. The control circuitry is configurable to: provide first control signals to the control terminal of the first switch and the control terminal of the second switch responsive to detecting a soft-switching event; and provide second control signals to the control terminal of the first switch and the control terminal of the second switch responsive to detecting a hard-switching event, the second control signals different than the first control signals.

In some examples, the transistor is a first transistor and the IC package further comprises: an LDO (e.g., the LDO 380 in FIG. 3) having a first terminal and a second terminal; and a second transistor (e.g., the transistor M2 in FIG. 3) having a first terminal, a second terminal, and a control terminal. The first terminal of the second transistor is coupled to the second terminal of the LDO. The second terminal of the second transistor is coupled to the control terminal of the first transistor.

In some examples, the IC package includes: a first capacitor (e.g., C1 in FIG. 3) having a first terminal and a second terminal, the first terminal of the first capacitor coupled to the control terminal of the first transistor, and the second terminal of the first capacitor coupled to the first terminal of the first transistor; and a second capacitor (e.g., C2 in FIG. 3) having first terminal and a second terminal, the first terminal of the second capacitor coupled to the first terminal of the first transistor.

In some examples, the first switch has a first control terminal (e.g., the control terminal T3 of the switch S1 in FIG. 3), the second switch has a second control terminal (e.g., the control terminal T3 of the switch S2 in FIG. 3), and the IC package further comprises control circuitry (e.g., the control circuitry 350 in FIG. 3) having a first terminal (e.g., the first terminal 352 in FIG. 3) and a set of second terminals (e.g., the set of second terminals 354 in FIG. 3). The first terminal of the control circuitry is coupled to the second terminal of the second capacitor. Respective terminals of the set of second terminals of the control circuitry are coupled to the first control terminal of the first switch, the second control terminal of the second switch, and the control terminal of the second transistor.

In some examples, the first transistor (e.g., M1 in FIG. 3, the first capacitor (e.g., C1 in FIG. 3), and the second capacitor (e.g., C2 in FIG. 3) are on a first die (e.g., the first die 302 in FIG. 3), and the first current source (e.g., the first current source 338 in FIG. 3), the first switch (e.g., the switch S1 in FIG. 3), the second current source (e.g., the second current source 344 in FIG. 3), the second switch (e.g., the switch S2 in FIG. 3, the LDO (e.g., the LDO 380 in FIG. 3), the second transistor (e.g., the transistor M2 in FIG. 3), and the control circuitry (e.g., the control circuitry 350 in FIG. 3) are on a second die (e.g., the second die 312 in FIG. 3). In some examples, the first current source includes sourcing current mirror circuitry (e.g., the first current source 602 and related components in FIG. 6), the second current source includes sinking current mirror circuitry (e.g., the second current source 802 and related components in FIG. 8), the control circuitry includes voltage transition detection circuitry (e.g., the voltage transition detection circuitry 364 in FIG. 3, the voltage transition detection circuitry 902 in FIG. 9, or the voltage transition detection circuitry 1002 in FIG. 10. The voltage transition detection circuitry includes: a third capacitor (e.g., C_{SNS} in FIGS. 9 and 10); a variable resistor (e.g., the variable resistor R_{DET} in FIGS. 9 and 10), a third switch (e.g., the switch S3 in FIGS. 9 and 10), a variable capacitor (e.g., the variable capacitor C_{DET} in FIGS. 9 and 10); a fourth switch (e.g., the switch S4 in FIGS. 9 and 10); a third transistor (e.g., the transistor M17 in FIGS. 9 and 10); a diode (e.g., the diode D2 in FIGS. 9 and 10); and a Schmitt trigger (e.g., the Schmitt trigger 912 in FIG. 9, or the Schmitt trigger 1012 in FIG. 10).

The third capacitor has a first terminal and a second terminal. The variable resistor has a first terminal, a second terminal, and a control terminal. The third switch is between the second terminal of the trimmable resistor and the second terminal of the third capacitor. The variable capacitor has a first terminal, a second terminal, and a control terminal. The fourth switch is between the first terminal of the trimmable capacitor and the second terminal of the third capacitor. The third transistor has a first terminal, a second terminal, and a control terminal. The first terminal of the third transistor is coupled to the first terminal of the trimmable resistor. The second terminal of the third transistor is coupled to the second terminal of the third capacitor. The diode has a first terminal and a second terminal. The first terminal of the diode is coupled to the second terminal of the trimmable capacitor. The second terminal of the diode is coupled to the second terminal of the third capacitor. The Schmitt trigger has a first terminal and a second terminal. The first terminal of the Schmitt trigger coupled to the second terminal of the third capacitor.

In some examples, the Schmitt trigger has an enable terminal (e.g., the second terminal 1016 in FIG. 10), and the voltage transition detection circuitry includes blanking delay circuitry (e.g., the blanking delay circuitry 1020 in FIG. 10) having a first terminal (e.g., the first terminal 1022 in FIG. 10) and a second terminal (e.g., the third terminal 1026 in FIG. 10). The first terminal of the blanking delay circuitry is coupled to the second terminal of the third capacitor. The second terminal of the blanking delay circuitry is coupled to the enable terminal of the Schmitt trigger.

In some examples, an IC package (e.g., an IC package with the controller 148 in FIG. 1, the controller 248 in FIG. 2, circuitry of the first die 302 and/or the second die 312 in FIG. 3, or related circuits in FIGS. 6 to 10) includes: a GaN transistor (e.g., the HS switch 120 in FIG. 1, the LS switch 128 in FIG. 1, the first switch 228 in FIG. 2, the second switch 236 in FIG. 2, the transistor M1 in FIG. 3) having a first terminal, a second terminal, and a control terminal; and driver circuitry (e.g., the seesaw driver and control circuitry 184 in FIG. 1, the seesaw driver and control circuitry 284 in FIG. 2, the seesaw driver circuitry 322 in FIG. 3, or related circuits in FIGS. 6 to 10) having a set of first terminals (e.g., the set of first terminal 326 in FIG. 3), a second terminal (e.g., the fourth terminal 332 in FIG. 3), and a third terminal (e.g., the sixth terminal 336 in FIG. 3). The third terminal of the driver circuitry is coupled to the control terminal of the GaN transistor. The driver circuitry includes: a first current source (e.g., the first current source 338 in FIG. 3, or the first current source 602 in FIG. 6); a first switch (e.g., the switch S1 in FIG. 3) between the first current source and the third terminal of the driver circuitry, the first switch having a control terminal; a second current source (e.g., the second current source 344 in FIG. 3, or the second current source 802 in FIG. 8); a second switch (e.g., the switch S2) between the second current source and the third terminal of the driver circuitry, the second switch having a control terminal; and a second transistor (e.g., the transistor M2) between the second terminal of the driver circuitry and the third terminal of the driver circuitry.

In some examples, the IC package includes control circuitry coupled to the first switch and the second switch. The control circuitry is configurable to: provide first control signals to the control terminal of the first switch and the control terminal of the second switch responsive to detecting a soft-switching event; and provide second control signals to the control terminal of the first switch and the control terminal of the second switch responsive to detecting a hard-switching event, the second control signals different than the first control signals. In some examples, the control circuitry has a first terminal and a set of second terminals. The first terminal of the control circuitry is coupled to the first terminal of the first transistor. Terminals of the set of second terminals of the control circuitry are coupled to respective terminals of the set of first terminals of the driver circuitry. The control circuitry is configurable to: receive a voltage (e.g., Vos herein) at the first terminal of the control circuitry; receive a first control signal (e.g., the PWM signal herein); and, in response to the voltage decreasing before or while the first control signal transitions to an on-state, adjust second control signals at the set of third terminals of the control circuitry.

In some examples, the second control signals include control signals for the first switch, the second switch, and the second transistor during different control phases. In some examples, the voltage is a first voltage and the different control phases include: a first control phase (e.g., the first control phase 402 in FIG. 4) in which a second voltage (e.g., V_{GS} herein) at the control terminal of the GaN transistor is less than a first threshold; a second control phase in which current through the GaN transistor increases; a third control phase in which the first voltage decreases; and a fourth control phase initiated after the first voltage drops below a second threshold. In some examples, the GaN transistor is on a first die, the driver circuitry is on a second die, and the control circuitry is on the second die.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device “configured to” or “configurable to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component and/or a conductor.

A circuit or device described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field-effect transistor (“FET”) such as an NFET or a PFET, a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control terminal and its first and second terminals. In the context of a FET, the control terminal is the gate, and the first and second terminals are the drain and source. In the context of a BJT, the control terminal is the base, and the first and second terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. A circuit comprising:
a transistor having a first terminal, a second terminal, and a control terminal;
driver circuitry having a set of first terminals and a second terminal; and
control circuitry having a first terminal and a set of second terminals, the first terminal of the control circuitry coupled to the first terminal of the transistor, each terminal of the set of second terminals of the control circuitry coupled to a respective terminal of the set of first terminals of the driver circuitry, wherein the control circuitry is configurable to:
monitor a voltage at the first terminal of the control circuitry;
monitor a state of a first control signal;
identify a switching event for the transistor as a soft-switching event responsive to the voltage and the first control signal; and
in response to identifying the switching event for the transistor as a soft-switching event, adjust second control signals at the set of second terminals of the control circuitry.

2. The circuit of claim 1, wherein the control circuitry is configurable to identify the switching event for the transistor as a soft-switching event responsive to the voltage decreasing before or while the first control signal transitions to an on-state.

3. The circuitry of claim 2, wherein the voltage is a first voltage and the control circuitry is configurable to:
identify a switching event for the transistor as a hard-switching event; and
in response to identifying the switching event for the transistor as a hard-switching event, adjust second control signals at the set of second terminals of the control circuitry to modulate current during different control phases, the different control phases including:
a first control phase in which a second voltage at the second terminal of the driver circuitry is less than a first threshold;
a second control phase in which current through the transistor increases;
a third control phase in which the first voltage is decreasing; and
a fourth control phase initiated after the first voltage drops below a second threshold.

4. The circuitry of claim 3, wherein the modulated current includes: a fixed positive current level during some of the first control phase and during the second control phase; a negative current level during the third control phase; and a negative ramp then a zero current level during the fourth control phase.

5. The circuitry of claim 4, wherein the driver circuitry has a third terminal, the fourth control phase is a pull-up phase in which a pull-up voltage is received at the third terminal of the driver circuitry.

6. The circuit of claim 1, wherein the circuit is part of an integrated circuit package that includes a die with the transistor and the driver circuitry.

7. The circuit of claim 1, wherein the circuit is part of an integrated circuit package that includes a first die with the transistor and a second die with the driver circuitry.

8. The circuit of claim 1, wherein the transistor is a gallium nitride (GaN) transistor.

9. An integrated circuit (IC) package comprising:
a gallium nitride (GaN) transistor having a first terminal, a second terminal, and a control terminal;
a first current source having a first terminal and a second terminal;
a first switch coupled between the second terminal of the first current source and the control terminal of the transistor;
a second current source having a first terminal and a second terminal;
a second switch between the second terminal of the second current source and the control terminal of the transistor; and
control circuitry coupled to the first switch and the second switch, the control circuitry configurable to:
provide first control signals to the first switch and the second switch responsive to detecting a soft-switching event; and
provide second control signals to the first switch and the second switch responsive to detecting a hard-switching event, the second control signals different than the first control signals.

10. The IC package of claim 9, wherein the transistor is a first transistor and the IC package further comprises:
a low dropout regulator (LDO) having a first terminal and a second terminal; and
a second transistor having a first terminal, a second terminal, and a control terminal, the first terminal of the second transistor coupled to the second terminal of the LDO, and the second terminal of the second transistor coupled to the control terminal of the first transistor.

11. The IC package of claim 10, further comprising:
a first capacitor having a first terminal and a second terminal, the first terminal of the first capacitor coupled to the control terminal of the first transistor, and the second terminal of the first capacitor coupled to the first terminal of the first transistor; and
a second capacitor having first terminal and a second terminal, the first terminal of the second capacitor coupled to the first terminal of the first transistor.

12. The IC package of claim 11, wherein the first switch has a first control terminal, the second switch has a second control terminal, and the IC package further comprises control circuitry having a first terminal and a set of second terminals, the first terminal of the control circuitry is coupled to the second terminal of the second capacitor, respective terminals of the set of second terminals are coupled to the first control terminal of the first switch, the second control terminal of the second switch, and the control terminal of the second transistor.

13. The IC package of claim 12, wherein the first transistor, the first capacitor, and the second capacitor is on a first die, and the first current source, the first switch, the second current source, the second switch, the LDO, the second transistor, and the control circuitry are on a second die.

14. The IC package of claim 9, wherein the first current source includes sourcing current mirror circuitry and the second current source includes sinking current mirror circuitry.

15. The IC package of claim 12, wherein the control circuitry includes voltage transition detection circuitry, and the voltage transition detection circuitry includes:
a third capacitor having a first terminal and a second terminal;
a trimmable resistor having a first terminal, a second terminal, and a control terminal;
a third switch between the second terminal of the trimmable resistor and the second terminal of the third capacitor;
a trimmable capacitor having a first terminal, a second terminal, and a control terminal;
a fourth switch between the first terminal of the trimmable capacitor and the second terminal of the third capacitor;
a third transistor having a first terminal, a second terminal, and a control terminal, the first terminal of the third transistor coupled to the first terminal of the trimmable resistor, and the second terminal of the third transistor coupled to the second terminal of the third capacitor;
a diode having a first terminal and a second terminal, the first terminal of the diode coupled to the second terminal of the trimmable capacitor, and the second terminal of the diode coupled to the second terminal of the third capacitor; and
a Schmitt trigger having a first terminal and a second terminal, the first terminal of the Schmitt trigger coupled to the second terminal of the third capacitor.

16. The IC package of claim 15, wherein the Schmitt trigger has an enable terminal, and the voltage transition detection circuitry includes blanking delay circuitry having a first terminal and a second terminal, the first terminal of the blanking delay circuitry coupled to the second terminal of the third capacitor, and the second terminal of the blanking delay circuitry is coupled to the enable terminal of the Schmitt trigger.

17. An integrated circuit (IC) package comprising:
a gallium nitride (GaN) transistor having a first terminal, a second terminal, and a control terminal;
driver circuitry having a set of first terminals, a second terminal, and a third terminal, the third terminal of the driver circuitry coupled to the control terminal of the GaN transistor, and the driver circuitry including:
a first current source;
a first switch between the first current source and the third terminal of the driver circuitry, the first switch having a control terminal;
a second current source;
a second switch between the second current source and the third terminal of the driver circuitry, the second switch having a control terminal; and
a second transistor between the second terminal of the driver circuitry and the third terminal of the driver circuitry, and
control circuitry coupled to the control terminal of the first switch and the control terminal of the second switch, the control circuitry configurable to:
provide first control signals to the control terminal of the first switch and the control terminal of the second switch responsive to detecting a soft-switching event; and
provide second control signals to the control terminal first switch and the control terminal of the second switch responsive to detecting a hard-switching event, the second control signals different than the first control signals.

18. The IC package of claim 17, wherein the control circuitry has a first terminal and a set of second terminals, the first terminal of the control circuitry coupled to the first terminal of the first transistor, terminals of the set of second terminals of the control circuitry coupled to respective terminals of the set of first terminals of the driver circuitry, and the control circuitry configurable to:
receive a voltage at the first terminal of the control circuitry;
receive a first control signal; and
in response to the voltage decreasing before or while the first control signal transitions to an on-state, adjust second control signals at the set of second terminals of the control circuitry.

19. The IC package of claim 18, wherein the voltage is a first voltage, the second control signals include control signals for the first switch, the second switch, and the second transistor, and the control circuitry is configurable to:
identify a switching event for the transistor as a hard-switching event; and
in response to identifying the switching event for the transistor as a hard-switching event, adjust second control signals at the set of second terminals of the control circuitry to modulate current during different control phases, the different control phases including:
a first control phase in which a second voltage at the control terminal of the GaN transistor is less than a first threshold; a second control phase in which current through the GaN transistor increases; a third control phase in which the first voltage decreases; and a fourth control phase initiated after the first voltage drops below a second threshold.

20. The IC package of claim 18, wherein the GaN transistor is on a first die, the driver circuitry is on a second die, and the control circuitry is on the second die.
